(19) United States
(12) Patent Application Publication
(10) Pub. No.: US 2009/0209095 A1
(43) Pub. Date: Aug. 20, 2009

(54) Manufacturing Method for Semiconductor Devices and Substrate Processing Apparatus

(76) Inventor: Sadayoshi Horii, Toyama-shi (JP)

Correspondence Address: KRATZ, QUINTOS & HANSON, LLP, 1420 K Street, N.W., Suite 400, WASHINGTON, DC, 20005, US

(21) Appl. No.: 11/922,344

(22) PCT Filed: Jun. 13, 2006
(86) PCT No.: PCT/JP2006/311788

§ 371 Date: Apr. 22, 2008

(30) Foreign Application Priority Data
Jun. 22, 2005 (JP) 2005-182494

(51) Int. Cl. H01L 21/28; B05C 11/00

(52) U.S. Cl. 438/585; 118/695; 257/E21.19

(57) ABSTRACT

The throughput in the overall gate stack forming process is improved. When using a cluster apparatus to perform a gate stack forming process including a high dielectric film forming step, a plasma nitriding step, an annealing step and a gate electrode forming step, the final ongoing gate electrode forming step is stopped in the middle, and the remainder of the gate electrode forming step is performed on multiple wafers as batch processing. This shortens the standby time for consecutive steps in the cluster apparatus to improve the throughput in the overall gate stack forming process.

### TECHNICAL FIELD

The present invention relates to a substrate processing apparatus and a semiconductor device manufacturing method, and for example, is effective for the process of forming MOSFET (Metal Oxide Semiconductor Field Effect Transistors) gate stack structures on semiconductor wafers (hereafter called wafers) for making integrated circuits including semiconductor devices in a semiconductor device manufacturing method for semiconductor integrated circuit devices (hereafter called IC).

### BACKGROUND ART

Silicon oxide (SiO₂) film is generally used in the gate insulating film for MOSFET which are one component making up the IC.

In recent years, gate insulating films must be made even thinner to provide greater electrical capacitance with progress made in shrinking the minimum dimensions of the IC.

However, making the silicon oxide film to 2 nanometers or thinner, increases the leak current, raising the concern that silicon oxide might no longer be usable in the MOSFET.

Rather than making the film thinner, studies are being made into using metal oxide films with dielectric constant higher than silicon oxide film, in particular using silicate films which are a type of metal oxide film containing silicon in the gate insulating film in order to increase the electrical capacitance. Among silicate films, hafnium silicate (HfₓSi_{y}O₂) film appears a particularly promising candidate due to thermal stability.

However, in the MOSFET gate forming process utilized in conventional IC manufacturing methods, a polycrystalline silicon (Poly-Si) film is first formed as a gate electrode on the gate insulating film, a dopant for electrical conduction is then implanted, and active annealing is performed along with the dopant for MOSFET source and drain sections.

The active annealing process temperature is typically about 1,000° C.

Hafnium silicate film as the gate insulating film in the conventional MOSFET gate forming process, has been subjected to a process temperature of approximately 1,000° C. in the active annealing so that the HfO and SiO in the hafnium silicate film mutually diffuse and respectively separate into hafnium oxide (HfO₂) and silicon oxide (SiO₂), causing the problem that the hafnium oxide crystallizes.

When the hafnium oxide crystallizes, a leakage current propagates along the boundary between the crystallized hafnium oxide and the silicon oxide serving as the amorphous section, leading to a phenomenon where the MOSFET can no longer function.

Adding nitrogen atoms to the hafnium silicate film was proposed in order to prevent mutual diffusion of the HfO and SiO.

These nitrogen atoms for example, are diffused into the hafnium silicate film utilizing nitrogen plasma, and then bonded with the silicon atoms, hafnium atoms and oxygen atoms by annealing to be stabilized. As a result, a hafnium oxynitride (HfₓSi_{y}ON) film serving as the gate insulating film is formed.

The process for forming a gate stack (gate insulating film—gate electrode) structure utilizing this hafnium oxynitride film requires using in sequence, a hafnium silicate film forming CVD apparatus, a plasma nitriding apparatus, annealing apparatus and a polycrystalline silicon film forming CVD apparatus; respectively in a hafnium silicate film forming step, a nitrogen diffusion step by a plasma nitriding method, a step for stabilizing the nitrogen by annealing and a step for forming a polycrystalline silicon film.

Performing these four steps is usually thought to require these four apparatus.

In this case, however, the wafer is exposed to air in the period where transported from the apparatus where the previous step was performed to the apparatus for performing the next step. Moisture in the air is adsorbed on the surface of the film formed on the wafer.

If the next step is executed while moisture is still adsorbed on the surface film, then that moisture is absorbed into the film, causing the insulating properties of the insulating film to deteriorate, and a layer with a low dielectric constant to form at the interface of the electrode and insulating film leading to a drop in the electrical capacitance of the gate stack structure and deterioration in the resistance constant of the polycrystalline silicon electrode.

Whereupon the idea of performing the above four steps by utilizing an apparatus called a cluster tool (hereafter, called a cluster apparatus) that connects the hafnium silicate film forming CVD apparatus, plasma nitriding apparatus, annealing apparatus and a polycrystalline silicon film forming CVD apparatus in one vacuum transfer chamber was conceived.

A non-patent document 1 discloses an example of a cluster apparatus for consecutively performing in-situ the steps from forming the interface control layer on the silicon wafer surface to forming the High-K (high dielectric constant) gate insulating film.

Non-patent document 1: “Electronic Materials, December, 2004 issue” Kogyo Chosakai Publishing Co., Ltd. Nov. 26, 2004, p. 44 to 48

### DISCLOSURE OF INVENTION

### Problems to be Solved by Invention

A cluster apparatus containing the four devices described above must process a maximum number of pieces (throughput) per unit of time in view of the need for cost performance. Therefore, the processing time of each of the four devices must not only be short but must also be equal to each other.

If the processing time for one device is long, then the processing time of the cluster apparatus will be limited to the processing time of that one device, no matter how short the processing times of the other three devices.

For example, the film processing time for a High-K film with a thickness of 2 to 4 nanometers, plasma processing time and annealing time are respectively completed within normally a few minutes, but forming of the 100 to 150 nanometers thick film in the electrode forming process takes 10 minutes or more, then there is a problem of poor throughput in the cluster apparatus.

Here, we described the case where utilizing hafnium silicate film as the high dielectric film. However, the same problem may occur when using a combination of metal electrode and hafnia, hafnium aluminate film or other films called a high dielectric.

An object of the present invention is to provide a substrate processing apparatus and a semiconductor device manufacturing method capable of achieving a maximum throughput, as well as a shortened processing time in the overall process.

### Means to Solve the Problems

Typical aspects of the present invention are described as follows.

(1) A manufacturing method for semiconductor devices comprising the steps of:

performing different processes consecutively on at least one substrate at a time,

stopping in the middle, the final ongoing process among the consecutive processes, and

performing the remainder of the final process that was stopped as batch processing of the multiple substrates.

(2) The manufacturing method for semiconductor devices according to the first (1) aspect, wherein the batch processing of the multiple substrates is performed in a processing chamber storing the multiple substrates.
(3) The manufacturing method for semiconductor devices according to the first (1) aspect, wherein the batch processing of the multiple substrates is performed using multiple processing chambers storing at least one substrate in each processing chamber.
(4) The manufacturing method for semiconductor devices according to the first (1) aspect, wherein the batch processing of the multiple substrates is performed in a unit of the substrates stored in one substrate storage container.
(5) The manufacturing method for semiconductor devices according to the first (1) aspect, wherein the batch processing of the multiple substrates is performed in a unit of 25 substrates.
(6) The manufacturing method for semiconductor devices according to the first (1) aspect, wherein the batch processing of the multiple substrates is performed using different apparatus from the apparatus for performing the consecutive processes.
(7) The manufacturing method for semiconductor devices according to the first (1) aspect, wherein each process in the consecutive processes is performed in different processing chambers respectively.
(8) The manufacturing method for semiconductor devices according to the first (1) aspect, wherein the processing time for the final process in the consecutive processes is set to the same or shorter processing time than the processing time for the process with the longest processing time among the other processes in the consecutive processes.
(9) The manufacturing method for semiconductor devices according to the first (1) aspect, wherein the consecutive processes include at least a step of forming an insulating film on the substrate, and a step of forming an electrode on the insulating film, and the final process is the step of forming the electrode.
(10) The manufacturing method for semiconductor devices according to the first (1) aspect, wherein the consecutive processes include at least a step of forming a High-k film on the substrate, and a step of forming an electrode on the High-k film, and the final process is the step of forming the electrode.
(11) The manufacturing method for semiconductor devices according to the first (1) aspect, wherein the consecutive processes include at least a step of forming a High-k film on the substrate, a step of nitriding the High-k film, a step of annealing the nitrided High-k film, and a step of forming an electrode on the High-k film after annealing, and the final process is the step of forming the electrode.
(12) A substrate processing apparatus comprising:

a consecutive processing apparatus including multiple processing chambers for performing different processes consecutively on at least one substrate at a time, and a controller for controlling to stop in the middle, the final ongoing process in the consecutive processes and;

a batch processing apparatus including one or multiple processing chambers for batch processing multiple substrates with identical process, and a controller for controlling to perform the remainder of the process that was stopped in the consecutive processing apparatus, in the one or multiple processing chambers as batch processing of the multiple substrates.

### EFFECT OF INVENTION

The present invention according to the first (1) aspect stops in the middle, the ongoing final process in the consecutive processes and can therefore shorten the processing time in the overall consecutive processing as well as achieve a maximum throughput.

### BRIEF DESCRIPTION OF DRAWINGS

FIG. 1 is a flowchart showing the gate stack forming process for forming the MOSFET gates in an embodiment of the present invention;

FIG. 2 is a plan cross sectional view showing the cluster apparatus of an embodiment of this invention;

FIG. 3 is a front cross sectional view showing the single-wafer ALD apparatus;

FIG. 4 is a front cross sectional view showing the MMT apparatus;

FIG. 5 is a front cross sectional view showing the RTP apparatus;

FIG. 6 is a partially cut front view showing the single-wafer CVD apparatus;

FIG. 7 is a partially cut front view showing the batch CVD apparatus;

FIG. 8 is an enlarged cross sectional view of a portion of that apparatus;

FIG. 9 is a sequence chart showing the gate stack forming process in the comparative example;

FIG. 10 is a sequence chart showing the gate stack forming process of the present embodiment;

FIG. 11 is a plan view showing the multi-chamber apparatus containing two single-wafer CVD apparatus utilized in the step for forming the remaining gate electrode in the gate stack forming process in another embodiment of the present invention;

FIG. 12 is a partially cut plan view showing the cluster apparatus containing the batch CVD apparatus utilized in the step for forming the remaining gate electrode in the gate stack forming process in still another embodiment of the present invention;

FIG. 13 is a side cross sectional view showing the stack type multi-chamber apparatus as another embodiment of the present invention utilized in the step for forming the remaining gate electrode in the gate stack forming process.

### BEST MODE FOR CARRYING OUT THE INVENTION

An embodiment of the present invention is described next while referring to the drawings.

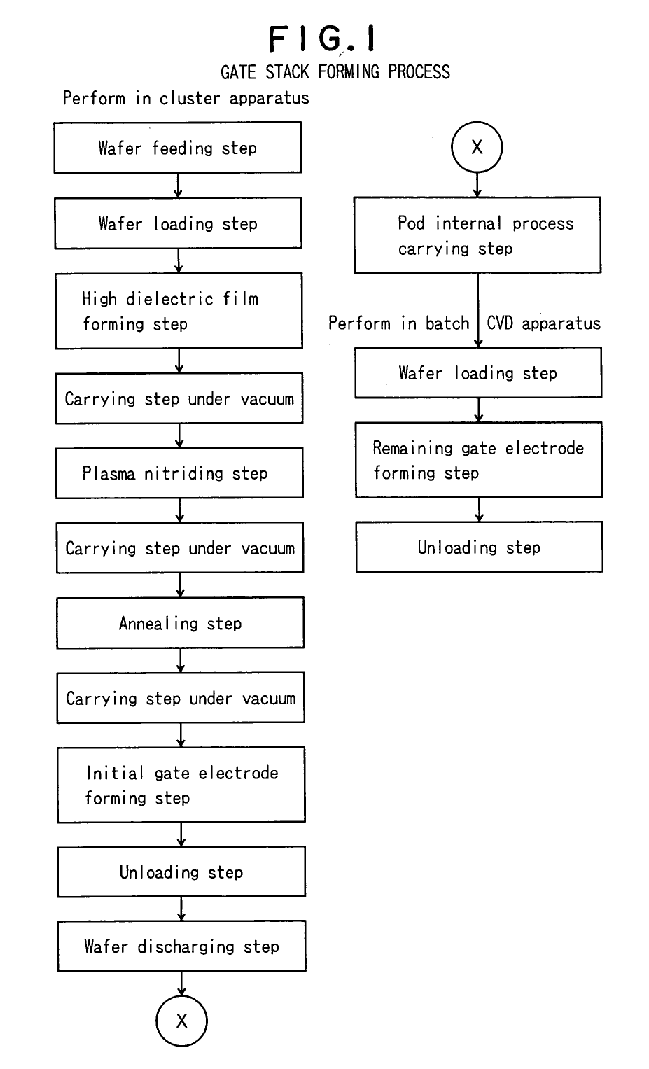

FIG. 1 is a flowchart showing the gate stack forming process for the MOSFET in the IC manufacturing method of an embodiment of the present invention.

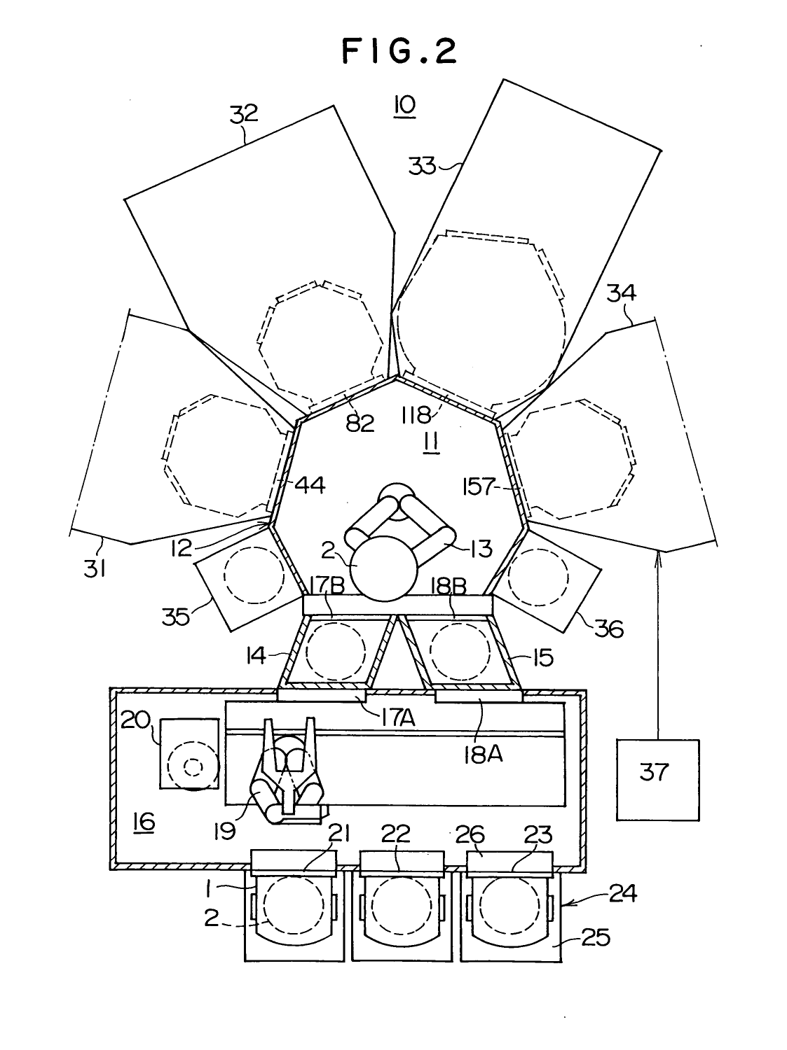

FIG. 2 and onwards show the substrate processing apparatus in an embodiment of the present invention.

The substrate processing apparatus in an embodiment of the present invention is described first.

The substrate processing apparatus of this invention in this embodiment is the cluster apparatus as shown structurally in FIG. 2, and functionally is used in the gate stack forming process for MOSFET.

The cluster apparatus in this embodiment utilizes a FOUP (front opening unified pod. Hereafter called, pod) 1, that serves as the wafer carrier (substrate storage container) for transferring wafers 2.

The cluster apparatus 10 as shown in FIG. 2, includes a first wafer transfer chamber (hereafter, called, negative pressure transfer chamber) 11 built as a structure for withstanding the pressure (negative pressure) below atmospheric pressure. A case (Hereafter called negative pressure transfer chamber case) 12 of the negative pressure transfer chamber 11 is made up of a heptagonal shape as seen from a plan view and possesses a box-like shape sealed at the top and bottom ends.

A wafer transfer device (Hereafter called negative pressure transfer device) 13 for transferring the wafer 2 under negative pressure is installed in the center section of the negative pressure transfer chamber 11. This negative pressure transfer device 13 is made up of a SCARA robot (SCARA: selective compliance assembly robot arm).

A carry-in prechamber (Hereafter called carry-in chamber) 14 and a carry-out prechamber (Hereafter called carry-out chamber) 15 respectively adjoin and connect to the long side wall among the seven side walls in the negative pressure transfer chamber case 12.

The cases for the carry-in chamber 14 and the carry-out chamber 15 respectively form a diamond shape as seen from a plan view and possess box-like shapes sealed at the top and bottom ends. These cases also are made up of a loadlock chamber structure for withstanding negative pressure.

A second wafer transfer chamber (Hereafter called positive pressure transfer chamber) 16 capable of maintaining atmospheric pressure or higher (Hereafter called positive pressure), adjoins and connects to the side opposite to the negative pressure transfer chamber 11 of the carry-in chamber 14 and the carry-out chamber 15. The case for the positive pressure transfer chamber 16 is a rectangular shape along the lateral length as seen from a plan view and forms a box-like shape sealed at the top and bottom ends.

A gate valve 17A is installed on the boundary between the carry-in chamber 14 and the positive pressure transfer chamber 16. A gate valve 17B is installed between the carry-in chamber 14 and the negative pressure transfer chamber 11. A gate valve 18A is installed on the boundary between the carry-out chamber 15 and the positive pressure transfer chamber 16. A gate valve 18B is installed between the carry-out chamber 15 and the negative pressure transfer chamber 11.

A second wafer transfer device (Hereafter called positive pressure transfer device) 19 for transferring the wafer 2 under a positive pressure is installed in the positive pressure transfer chamber 16. The positive pressure transfer device 19 is a SCARA robot. An elevator installed in the positive pressure transfer chamber 16 raises and lowers the positive pressure transfer device 19. The positive pressure transfer device 19 is structured to move back and forth in the left and right directions by a linear actuator.

A notch aligner device 20 is installed on the left side of the positive pressure transfer chamber 16.

Three wafer carry-in/out ports 21, 22, 23 are formed arrayed adjacent to each other on the front wall of the positive pressure transfer chamber 16. These wafer carry-in/out ports 21, 22, 23 are set to allow carrying the wafer 2 in and out of the positive pressure transfer chamber 16. Pod openers 24 are installed in each of the wafer carry-in/out ports 21, 22, 23.

These pod openers 24 contain a mounting stand 25 for loading the pod 1, a cap fitter/remover 26 for fitting and removing the cap on the pod 1 installed on the mounting stand 25. The pod opener 24 opens and closes the wafer loading/unloading port of the pod 1 via the cap fitter/remover 26 fitting or removing the cap on the pod 1 loaded on the mounting stand 25.

An internal process transfer device (RGV) not shown in the drawing, supplies and ejects the pod 1 to the mounting stand 25 of the pod opener 24.

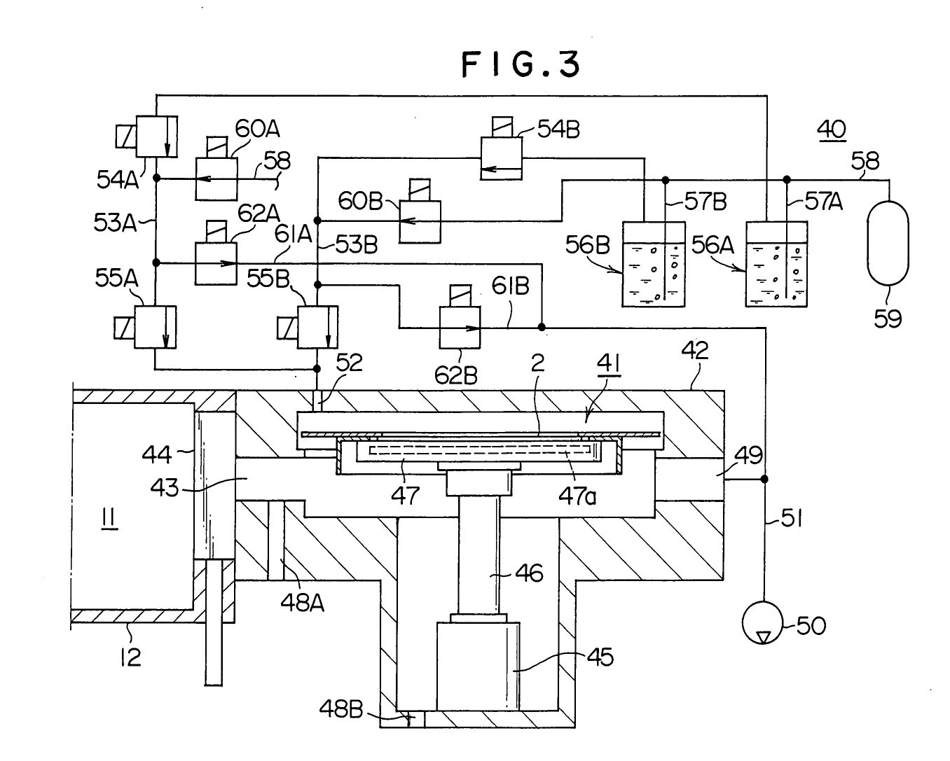

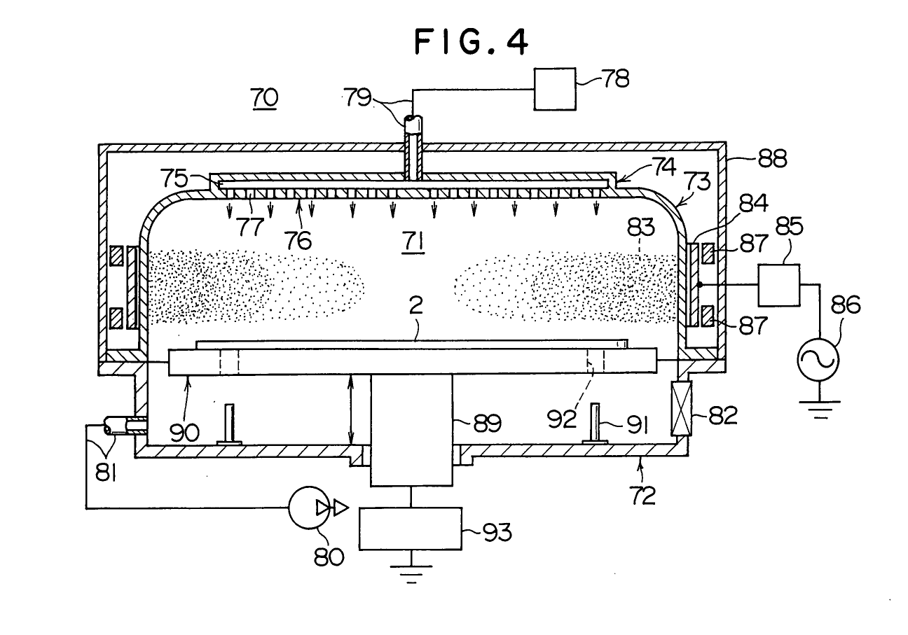

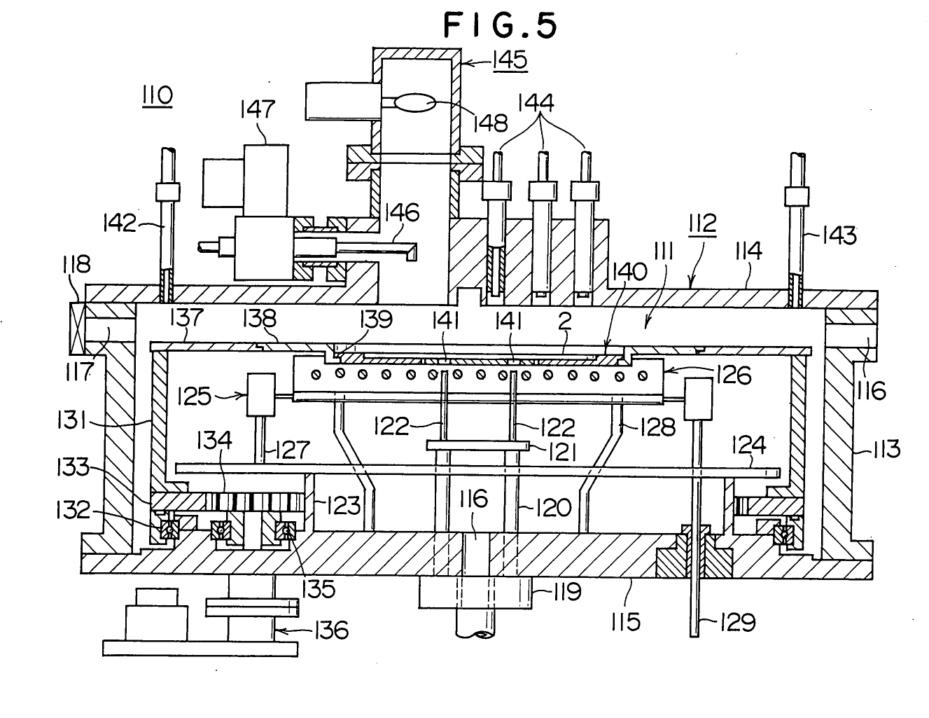

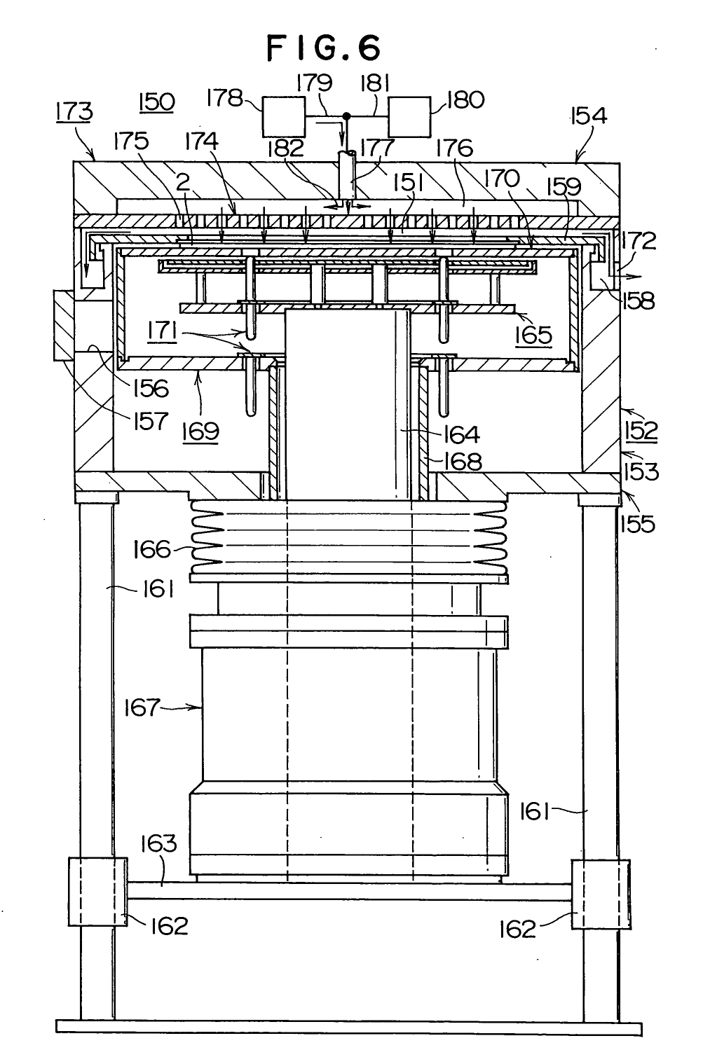

As shown in FIG. 2, a first processing unit 31 and, a second processing unit 32 and, a third processing unit 33 and, a fourth processing unit 34 are each adjacently connected to the four side walls positioned on the side opposite the positive pressure transfer chamber 16 among the seven side walls of the negative pressure transfer chamber case 12. A gate valve 44 (See FIG. 3) is installed between the negative pressure transfer chamber 11 and the first processing unit 31. A gate valve 82 (See FIG. 4) is installed between the second processing unit 32 and the negative pressure transfer chamber 11. A gate valve 118 (See FIG. 5) is installed between the third processing unit 33 and the negative pressure transfer chamber 11. A gate valve 157 (See FIG. 6) is installed between the fourth processing unit 34 and the negative pressure transfer chamber 11.

A first cooling unit 35 and a second cooling unit 36 are each connected to the two side walls remaining among the seven side walls on the negative pressure transfer chamber case 12. The first cooling unit 35 and the second cooling unit 36 are each structured so as to cool the processed wafer 2.

The cluster apparatus 10 contains a controller 37 for unified control of the sequence flow. The controller 37 in this embodiment is designed to perform control that stops in the middle, the ongoing gate electrode forming step as described later on.

The case where performing the gate forming process shown in FIG. 1 by using the cluster apparatus 10 structured as above is described next.

In the wafer loading step shown in FIG. 1, the cap fitter/remover 26 removes the cap of the pod 1 supplied to the mounting stand 25 of the cluster apparatus 10, and opens the wafer loading/unloading port of the pod 1.

When the pod 1 is opened, the positive pressure transfer device 19 installed in the positive pressure transfer chamber 16, picks up one wafer 2 at a time from the pod 1 via the wafer loading/unloading port and loads it into the carry-in chamber 14, and transfers the wafer 2 to the carry-in chamber temporary mounting stand.

During this transfer operation, the gate valve 17B closes the negative pressure transfer chamber 11 side of the carry-in chamber 14, and maintains a pressure for example of 100 Pa within the negative pressure transfer chamber 11.

In the wafer loading step shown in FIG. 1, the gate valve 17A closes the positive pressure transfer chamber 16 side of the carry-in chamber 14, and an exhaust device (not shown in drawing) exhausts the carry-in chamber 14 to a negative pressure. When the carry-in chamber 14 is depressurized to a preset pressure value, the gate valve 17B opens the negative pressure transfer chamber 11 side of the carry-in chamber 14.

Next, the negative pressure transfer device 13 in the negative pressure transfer chamber 11, picks up one wafer 2 at a time from the carry-in chamber temporary mounting stand and carries it into the negative pressure transfer chamber 11. The gate valve 17B then closes the negative pressure transfer chamber 11 side of the carry-in chamber 14.

The gate valve 44 of the first processing unit 31 then opens, and the negative pressure transfer device 13 transports the wafer 2 to the first processing unit 31 to implement the high dielectric film forming step shown in FIG. 1, and loads it into the processing chamber of the first processing unit 31.

During loading of wafer into the first processing unit 31, the oxygen and moisture are removed in advance by vacuum exhausting the carry-in chamber 14 and the negative pressure transfer chamber 11 so that oxygen and moisture are definitely prevented from penetrating into the processing chamber of the first processing unit 31 while the wafer is being carried into the first processing unit 31.

In this embodiment, the first processing unit 31 is structurally made up of a single-wafer warm-wall substrate processing apparatus as shown in FIG. 3; and functionally is made up of an ALD (Atomic Layer Deposition) apparatus 40 (Hereafter called the ALD apparatus).

The ALD apparatus 40 includes a case 42 forming a processing chamber 41 as shown in FIG. 3. This case 42 contains an internal heater (not shown in drawing) for heating the wall surfaces of the processing chamber 41.

A wafer carry-in/out port 43 is formed at the boundary with the negative pressure transfer chamber 11 of the case 42. The gate valve 44 opens and closes this wafer carry-in/out port 43.

An elevator drive unit 45 is installed at the bottom of the processing chamber 41 to raise and lower an up/down shaft 46. A support jig 47 for supporting the wafer is supported horizontally at the top end of the up/down shaft 46.

A heater 47a to heat the wafer 2 is installed on the support jig 47.

Purge gas supply ports 48A, 48B are respectively formed on the bottom walls of the processing chamber 41 and the wafer carry-in/out port 43. Purge gas supply lines (not shown in drawing) connect respectively to the purge gas supply ports 48A, 48B.

An exhaust port 49 is formed on a section of the side opposite the wafer carry-in/out port 43 of the case 42. An exhaust line 51 connected to an exhaust device 50 connects to the exhaust port 49.

A process gas supply port 52 in the ceiling wall of the case 42 is formed to connect to the processing chamber 41. A first process gas supply line 53A and a second process gas supply line 53B connect to the process gas supply port 52.

A first bubbler 56A connects via an upstream stop valve 54A and a downstream stop valve 55A to the first process gas supply line 53A. A bubbling pipe 57A of the first bubbler 56A connects to an argon gas supply line 58 that is connected to an argon gas supply source 59.

The argon gas supply line 58 is connected via a stop valve 60A between the upstream stop valve 54A and the downstream stop valve 55A on the first process gas supply line 53A. The upstream end of a vent line 61A is connected between the downstream stop valve 55A and the connection point with the argon gas supply line 58 of the first process gas supply line 53A. The downstream end of the vent line 61A connects to the exhaust line 51 connected to the exhaust device 50 via a stop valve 62A.

A second bubbler 56B connects by way of a downstream stop valve 55B and an upstream stop valve 54B to a second process gas supply line 53B. A bubbling pipe 57B of the second bubbler 56B connects to the argon gas supply line 58 connected to the argon gas supply source 59.

The argon gas supply line 58 connects by way of a stop valve 60B between the downstream stop valve 55B and the upstream stop valve 54B on the second process gas supply line 53B. The upstream end of a vent line 61B connects between the downstream stop valve 55B and the connection point with the argon gas supply line 58 of the second process gas supply line 53B. The downstream end of the vent line 61B connects by way of the stop valve 62B to the exhaust line 51 that is connected to the exhaust device 50.

The step of forming the high dielectric film shown in FIG. 1 is described next using the case where forming a high dielectric film of hafnium oxide (hafnia) film by the ALD method on the wafer 2 utilizing the above described ALD apparatus 40.

Material including hafnium atoms utilized when forming a hafnium oxide film as the high dielectric film include for example, TDMAH (Hf[N(CH₃)₂]₄: tetrakis-dimethylamino hafnium), TDEMAH (Hf[N(C₂H₅)₂]₄ tetrakis-diethylamino hafnium), TEMAH (Hf[N(CH₃)(C₂H₅)]₄ tetrakis-ethylmethylamino hafnium).

These materials are a liquid at room temperature and possess a high vaporizing pressure and so are utilized as a material gas vaporized by bubbling.

The ALD apparatus 40 of this embodiment uses the first bubbler 56A to vaporize the liquid hafnium material. The argon gas flow rate used for bubbling in the first bubbler 56A is 0.5 to 1 SLM (standard liters per minute).

Gas including oxygen atoms such as water vapor (H₂O) or ozone (O₃) is utilized as the oxidizer. An ozone generator is utilized if ozone is used.

The ALD apparatus 40 of this embodiment utilizes water vapor as an oxidizer. The second bubbler 56B is utilized to generate this water vapor. The argon gas flow rate used for bubbling in the second bubbler 56A is 0.5 to 1 SLM.

The gate valve 44 opens, the wafer 2 on which the hafnium oxide film is to be formed is loaded into the processing chamber 41 of the ALD apparatus 40 functioning as the first processing unit 31. The gate valve 44 closes the wafer carry-in/out port 43 as shown in FIG. 3 when the wafer is placed on the support jig 47.

The processing chamber 41 is exhausted by the exhaust device 50 to reach a specified pressure when the gate valve 44 closes. The internal heater 47a within the support jig 47 heats the wafer 2 to a specified temperature in the range of 150 to 500° C.

At the point in time where the wafer 2 is carried in, the stop valves 54A, 55A, 54B, and 55B are each in a closed state, and the stop valves 60A, 62A, 60B, and 62B are in an open state.

Besides closing the stop valves 60A, 55A, 60B, and 55B to prepare for supplying the material, the stop valves 54A, 62A, 54B, and 62B are opened in order to fill the first process gas supply line 53A and the second process gas supply line 53B respectively with vaporized hafnium material and water vapor.

The argon gas serving as the purge gas flows from the purge gas supply ports 48A, 48B at the rate of 0.1 to 1.5 SLM into the processing chamber 41.

The pressure within the processing chamber 41 is adjusted between 10 to 100 Pa.

After the temperature of the wafer 2 has stabilized, this cycle where the next steps (1) through (4) are one cycle, is repeated until the specified thickness of hafnium oxide film is reached.

(1) After the temperature of the wafer 2 has stabilized, the stop valve 62A is closed and the stop valve 55A is opened for the material supply step. This state is maintained unchanged for 0.5 to 5 seconds, and the vaporized hafnium material is supplied to the processing chamber 41. The hafnium material is in this way deposited on the surface of the wafer 2.

(2) Next, in the material exhausting step, the stop valve 54A is closed and the stop valve 60A is opened. This state is maintained unchanged for 0.5 to 10 seconds, and the first process gas supply line 53A and the processing chamber 41 are exhausted. The stop valves 60A and 55A are then closed, and the stop valves 54A and 62A are opened, and vaporized hafnium material is filled into the first process gas supply line 53A.

(3) Simultaneous with filling the vaporized hafnium material into the first process gas supply line 53A, the stop valve 62B is closed, and the stop valve 55B is opened as the oxidizing step. After maintaining that state for 0.5 to 15 seconds, water vapor is supplied as an oxidizer to the processing chamber 41. The hafnium material deposited on the surface of the wafer 2 in step (1) in this way reacts with the water vapor, and a hafnium oxide film with a thickness of approximately one angstrom (Å) is formed on the surface of the wafer 2.

(4) Next the stop valve 54B closes and the stop valve 60B opens as the exhausting step of the oxidizer. This state is maintained unchanged for 0.5 to 15 seconds, and the second process gas supply line 53B and the processing chamber 41 are exhausted. The stop valves 60B, 55B are next closed, the stop valves 54B, 62B opened, and water vapor filled into the second process gas supply line 53B.

A film thickness of approximately one angstrom (Å) is usually formed in one cycle in the ALD method, so that 20 or 30 cycles are required to obtain the target film thickness of 20 to 30 Å. If one cycle takes about 5 to 10 seconds, then forming the film of hafnium oxide will require 2 to 6 minutes.

After forming the hafnium oxide film is completed as described above, the gate valve 44 is opened, and the negative pressure transfer device 13 carries out the processed wafer 2 from the first processing unit 31 to the negative pressure transfer chamber 11 maintained at a negative pressure.

A gate valve 82 is opened after closing the gate valve 44, and the negative pressure transfer device 13 transports the wafer 2 to the second processing unit 32 to perform the plasma nitriding step shown in FIG. 1 and carries in the wafer into the processing chamber of the second processing unit 32.

In this embodiment, an MMT (Modified Magnetron Typed) apparatus 70 shown in FIG. 4 is utilized in the second processing unit 32.

The MMT apparatus 70 contains a processing chamber 71 as shown in FIG. 4. This processing chamber 71 includes a lower side container unit 72 and, an upper side container unit 73 covered on the top of the lower side container unit 72.

The upper side container unit 73 is formed in a dome shape from aluminum oxide or quartz. The lower side container unit 72 is formed from aluminum.

A shower head 74 forming a buffer chamber 75 serving as the gas diffusion space is installed above the upper side container unit 73. A shower plate 76 containing gas spray holes 77 serving as spray openings for gas is provided in the lower wall. A gas supply line 79 connected to the gas supply device 78 is connected to the upper wall of the shower head 74.

An exhaust line 81 connected to an exhaust device 80 is connected on the side wall of the lower side container unit 72. The gate valve 82 is also installed as a separator valve at another position on the side wall of the lower side container unit 72.

The negative pressure transfer device 13 carries the wafer 2 into and out of the processing chamber 71 while the gate valve 82 is open. The processing chamber 71 is maintained in an airtight state while the gate valve 82 is closed.

A tubular electrode 84 (preferably in a cylindrical shape) is installed concentrically on the outer side of the upper side container 73 as a discharge means to excite the reaction gas. The tubular electrode 84 encloses the plasma generation region 33 in the processing chamber 71. A high frequency power supply 86 for applying the high-frequency power is connected to the tubular electrode 84 by way of an impedance matcher 85 for adjusting the impedance.

A tubular magnet 87 is installed concentrically on the outer side of the tubular electrode 84 as tubular shaped (preferably in a cylindrical shape) magnetic field forming means. This tubular magnet 87 is installed near the upper and lower ends on the exterior side surface of the tubular electrode 84. The upper and lower tubular magnets 87, 87 contain magnetic poles on both (inner circumferential end and outer circumferential end) ends along the radius of the processing chamber 71. The poles of the upper and lower tubular magnets 87, 87 are set facing opposite each other. The magnetic poles at the inner circumference are of opposite polarity, and therefore form magnetic lines of force in this way on the tubular axis along the inner circumferential surface of the tubular electrode 84.

A cutoff plate 88 for effectively blocking the electrical field and magnetic field is installed on the perimeter of the tubular electrode 84 and the tubular magnets 87. This cutoff plate 88 blocks the electrical fields and magnetic fields formed by the tubular electrode 84 and the tubular magnets 87 to prevent adverse effects on the external environment, etc.

A susceptor up/down axis 89 driven up and down by an elevator, is supported for up and downward movement vertical in the center section of the lower side container unit 72. A susceptor 90 is installed horizontally on the top end of the processing chamber 71 side of the susceptor up/down axis 89 in order to support the wafer 2.

The susceptor up/down axis 89 is insulated from the lower side container unit 72. Three pushup pins 91 are erected vertically outward from the susceptor up/down axis 89 on the bottom of the lower side container unit 72. The three pushup pins 91 insert from the bottom, through three insertion holes 92 formed on the susceptor 90 during lowering of the susceptor up/down axis 89, and are structured to push up the wafer 2 held on the susceptor 90.

The susceptor 90 is formed in a disk shape with a diameter larger than the wafer 2 and is made from quartz as the dielectric. The susceptor 90 contains an internal heater (not shown in drawing).

An impedance adjuster unit 93 for adjusting the impedance is electrically connected to the susceptor 90. The impedance adjuster unit 93 contains a coil and a variable condenser. The impedance adjuster unit 93 controls the capacitance of the variable condenser and the number of coil patterns to regulate the electrical potential of the wafer 2 by way of the susceptor 90.

The plasma nitriding step shown in FIG. 1 is described next using the case where using the above described MMT apparatus 70 to add nitrogen (N₂) to the hafnium oxide film.

When the gate valve 82 opens, the wafer 2 now formed in the first processing unit 31 with a hafnium oxide film, is transferred by the negative pressure transfer device 13 to the processing chamber 71 of the MMT apparatus 70 serving as the second processing unit 32, and is mounted between the upper ends of the three pushup pins 91.

When the negative pressure transfer device 13 that transferred the wafer 2 to the pushup pins 91, retracts to outside the processing chamber 71, the gate valve 82 closes, the susceptor up/down axis 89 raises the susceptor 90, and as shown in FIG. 4, the wafer 2 is received on the susceptor 90 from the push-up pins 91.

The exhaust device 80 exhausts the interior of the processing chamber 71 to within a specified pressure of 0.5 to 200 Pa while the processing chamber 71 is sealed airtight.

A heater in the susceptor 90 is preheated. The heater heats the wafer 2 held in the susceptor 90 to a specified processing temperature within a range from room temperature to 950° C.

When the wafer 2 is heated to processing temperature, gas including nitrogen atoms such as nitrogen (N₂) gas and ammonia (NH₃) gas is supplied at a flow rate of 0.1 to 2 SLM to the processing chamber 71 from the gas supply device 78 and is fed as a shower via the gas spray holes 77 of the shower plate 76 and the gas supply line 79.

The high frequency power supply 86 supplies high-frequency power of 150 to 200 watts via the impedance matcher 85 to the tubular electrode 84. The high frequency waves are at this time regulated by the impedance matcher 85 so that the reflected wave is minimal.

Magnetron discharge is generated when the magnetic field effects from the tubular magnets 87, 87 are received, electrical charges are trapped in the space above the wafer 2, and a high-density plasma is generated in the plasma generation region 83.

The surface of the wafer 2 on the susceptor 90 is then subjected to plasma processing by the high-density plasma that was generated.

Nitrogen in a quantity matching the above processing conditions is added to the hafnium oxide film on the wafer 2, to change the hafnium oxide film to a hafnium oxynitride film.

The time for this processing is usually three to five minutes.

The gate valve 82 opens when a preset processing time elapses on the MMT apparatus 70. The negative pressure transfer device 13 carries the wafer 2 with nitrogen now added to the hafnium oxide film, out from the processing chamber 71 to the negative pressure transfer chamber 11 in the reverse sequence of the carry-in operation.

Next, the gate valve 118 opens after the gate valve 82 closes, and the negative pressure transfer device 13 transports the wafer 2 to the third processing unit 33 for implementing the annealing step shown in FIG. 1, and carries it into the processing chamber of the third processing unit 33.

In this embodiment, a RTP (Rapid Thermal Processing) apparatus 110 as shown in FIG. 5 is utilized in the third processing unit 33 for implementing the annealing step.

The RTP apparatus 110 as shown in FIG. 5, includes a case 112 forming a processing chamber 111 for processing the wafer 2. The case 112 includes a container 113 formed in a cylindrical shape open at the top and bottom ends, a top plate 114 in a disk shape for sealing the top opening of the container 113, and a bottom plate 115 in a disk shape for sealing the bottom opening of the container 113; all combining to form a hollowing cylindrical shape.

An exhaust port 116 is formed in a portion of the side wall of the container 113 to connect the interior and exterior of the processing chamber 111. An exhaust device (not shown in the drawing) connects to the exhaust port 116 to exhaust the processing chamber 111 to a level below atmospheric level (Hereafter, called negative pressure).

A wafer carry-in/out port 117 is formed at a position on a side opposite the exhaust port 116 on the side wall of container 113, to carry in or carry out the wafer 2 from the processing chamber 111. A gate valve 118 opens and closes the wafer carry-in/out port 117.

An up/down drive device 119 is installed along the centerline on the lower surface of the bottom plate 115. The up/down drive device 119 is structured to move an up/down axis 120 upward and downward inserted through the bottom plate 115, by a free upward/downward sliding movement versus the bottom plate 115.

An up/down plate 121 is fixed horizontally to the upper edge of the up/down axis 120. Multiple (usually 3 pins or 4 pins) lifter pins 122 are fastened perpendicularly erect on the top surface of the up/down plate 121. Each lifter pin 122 rises and lowers along with the up/down plate 121 so that the wafer 2 is raised and lowered while supported horizontally from below.

A support cylinder 123 is affixed to protrude to the outer side of the up/down axis 120 on the upper side of the bottom plate 115. A cooling plate 124 is affixed horizontally in top edge of the support cylinder 123.

A first heating lamp group 125 and a second heating lamp group 126 made up of multiple heating lamps are installed in order from below and are each affixed horizontally above the cooling plate 124. The first heating lamp group 125 and the second heating lamp group 126 are each supported horizontally by a first support pillar 127 and a second support pillar 128.

An electrical power supply wire 129 for the first heating lamp group 125 and the second heating lamp group 126 is inserted through the bottom plate 115 and drawn outwards.

A turret 131 is installed concentrically with the processing chamber 111 within the processing chamber 111. The turret 131 is affixed concentrically on the upper surface of an inner-toothed flat gear 133. This inner-toothed flat gear 133 is supported horizontally by a bearing 132 affixed on the bottom plate 115. A drive-side flat gear 134 engages with the inner-toothed flat gear 133. The drive-side flat gear 134 is horizontally supported by a bearing 135 affixed on the bottom plate 115. The drive-side flat gear 134 is driven to rotate by a susceptor swivel device 136 installed below the bottom plate 115.

An outer platform 137 formed in flat-plate ring shape is installed horizontally on the top edge of the turret 131. An inner platform 138 is affixed horizontally on the inner side of the outer platform 137.

A susceptor 140 held on the bottom edge on the inner circumferential side of the inner platform 138 engages with an engage piece 139 affixed to face inwards along the diameter on the bottom edge on the inner circumferential surface. Insertion holes 141 are respectively formed at positions facing each lifter pin 122 of the susceptor 140.

An anneal gas supply pipe 142 and an inert gas supply pipe 143 on the top plate 114, respectively connect to the processing chamber 111.

Multiple radiation thermometer probes 144 are inserted through the top plate 114 so as to face the upper surface of the wafer 2 and are respectively positioned apart from one another along the diameter from the center of the wafer 2. The radiation thermometer is structured to consecutively send the temperature measurements based on the radiant light detected by each of the multiple probes 144, to a controller.

A noncontacting radiation rate measurement device 145 for measuring the radiation rate of the wafer 2 is installed at other locations on the top plate 114. This radiation rate measurement device 145 includes a reference probe 146. A reference probe motor 147 rotates the reference probe 146 within a perpendicular plane.

A reference lamp 148 for beaming reference light is installed above the reference probe 146 so as to face the tip of the reference probe 146. The reference probe 146 is optically connected to a radiation thermometer. The radiation thermometer compares the photon density of the reference light from the reference lamp 148, with the photon density from the wafer 2 and in this way corrects the measurement temperature.

The annealing step shown in FIG. 1, for annealing of the plasma nitriding-processed hafnium oxide film using the above configure RTP apparatus is described next.

When the gate valve 118 opens, the negative pressure transfer device 13 transfers the wafer 2 for annealing into the processing chamber 111 of the RTP apparatus 110 serving as the third processing unit 33 from the wafer carry-in/out port 117 and transfers it between the top edge of the multiple lifter pins 122.

When the negative pressure transfer device 13 that transferred the wafer 2 onto the lifter pins 122, exits the processing chamber 111, the gate valve 118 closes the wafer carry-in/out port 117.

The up/down drive device 119 lowers the up/down axis 120 to transfer the wafer 2 on the lifter pins 122 onto the susceptor 140.

While the processing chamber 111 is sealed in an airtight state, the interior of the processing chamber 111 is exhausted via the exhaust port 116 to reach a specified pressure between 10 to 10,000 Pa.

When the susceptor 140 receives the wafer 2, the susceptor swivel device 136 swivels the turret 131 holding the wafer 2 on the susceptor 140, by way of the inner-toothed flat gear 133 and the drive-side flat gear 134.

The first heating lamp group 125 and the second heating lamp group 126 heat the wafer 2 held on the susceptor 140 to reach a specified temperature between 600 to 1,000° C., while the susceptor swivel device 136 rotates the wafer 2.

During this rotating and heating, the anneal gas supply pipe 142 supplies gas containing nitrogen atoms such as ammonia gas or nitrogen gas or gas containing oxygen atoms such as oxygen gas to the processing chamber 111.

The first heating lamp group 125 and the second heating lamp group 126 uniformly heat the wafer 2 held on the susceptor 140 while the susceptor swivel device 136 rotates the susceptor 140 so that the hafnium oxynitride film on the wafer 2 is uniformly annealed.

The processing time for this annealing is 5 to 120 seconds.

When a specified preset processing time elapses on the RTP apparatus 110, after the processing chamber 111 has been exhausted to the specified negative pressure via the exhaust port 116, the gate valve 118 opens, and the negative pressure transfer device 13 carries out the now annealed wafer 2 from the processing chamber 111 to the negative pressure transfer chamber 11 in the reverse sequence of the carry-in.

Next, the gate valve 157 opens after the gate valve 118 closes, and the negative pressure transfer device 13 transfers the wafer 2 to the fourth processing unit 34 for implementing the initial gate electrode forming step shown in FIG. 1 and carries the wafer 2 into the processing chamber of the fourth processing unit 34.

In the present embodiment, a single-wafer cold wall CVD apparatus (Hereafter called the single-wafer CVD apparatus) 150 as shown in FIG. 6 is utilized in the fourth processing unit 34.

The single-wafer CVD apparatus 150 contains a case 152 forming a processing chamber 151 for processing the wafer 2 as shown in FIG. 6. The case 152 is a combination made up of a lower container 153 and an upper container 154, and a bottom cap 155, and is formed in a cylindrical shape sealed at the top and bottom ends.

A wafer carry-in/out port 156 opened and closed by a gate valve 157 is formed in horizontally oblong position in the middle section in the cylindrical wall of the lower container 153 of the case 152. The wafer carry-in/out port 156 is formed to allow the negative pressure transfer device 13 to load/unload the wafer 2 into/from the processing chamber 151.

An exhaust buffer space 158 is formed in a ring shape on the top end of the lower container 153. A cover plate 159 formed in a circular ring shape covers the top of the exhaust buffer space 158. The inner circumferential section of the cover plate 159 is structured so as to cover the outer circumferential edge section of the wafer 2.

Multiple support rods 161 horizontally support the case 152. Elevator blocks 162 are respectively inserted into each support rod 161 for free upward and downward movement. An elevator stand 163 is affixed between these elevator blocks 162. An elevator drive device (not shown in drawing) utilizing the air cylinder devices is structured to raise and lower the elevator stand 163.

Insertion circular holes are formed in the center of the bottom caps 155 of the case 152. Cylindrical shaped support shafts 164 are inserted concentrically in the insertion holes from below into the processing chamber 151. These support shafts 164 are raised and lowered while supported on the elevator stands 163.

A heating unit 165 for heating the wafer 2 at the upper end of the support shaft 164 is installed concentrically and affixed horizontally. The support shaft 164 raises and lowers the heating unit 165.

A susceptor swivel device 167 using a brushless DC motor is installed above the elevator stand 163. A bellows 166 is installed between the susceptor swivel device 167 and the case 152 to seal the inner space. A rotating shaft 168 for the susceptor swivel device 167 is formed in a hollow shaft. The support shaft 164 is installed concentrically on the inner side of the rotating shaft 168.

The rotating shaft 168 rises and lowers along with the support shaft 164 while supported on the elevator stand 163 via the susceptor swivel device 167.

A rotating drum 169 is installed concentrically and affixed horizontally on the upper end of the rotating shaft 168. The rotating shaft 168 rotates the rotating drum 169.

The susceptor 170 seals the upper end opening on the upper end of the rotating drum 169.

A wafer elevator unit 171 is installed in the rotating drum 169. The wafer elevator unit 171 is structured to push up the wafer 2 perpendicularly from below the susceptor 170 to make the wafer 2 rise from the upper surface of the susceptor 170.

An exhaust port 172 for exhausting the processing chamber 151, is formed to connect to the exhaust buffer space 158, on the side wall facing the wafer carry-in/out port 156 at the top end of the lower container 153. One end of the exhaust line (not shown in drawing) connects to the exhaust port 172; and the other end of the exhaust line connects to an exhaust device (not shown in drawing) including a vacuum pump and a shutter valve and a variable flow rate control valve, etc.

A gas head 173 serving as the gas supply means is integrated into the upper container 154 of the case 152.

The gas head 173 contains a shower plate 174 held between the upper container 154 and the lower container 153. Multiple shower ports 175 are formed uniformly across the entire surface in the shower plate 174 to connect the upper and lower spaces. The internal space formed by the upper surface of the shower plate 174 and the lower and inner circumferential surfaces of the upper container 154 make up a gas accumulator 176. The end on the downstream side of a gas feed pipe 177 is inserted so as to connect to the gas accumulator 176, at a point facing the center of the shower plate 174 of the upper container 154.

A process gas supply line 179 connected to a process gas supply device 178; and an inert gas supply line 181 connected to an inert gas supply device 180 are connected to the gas feed pipe 177.

The initial gate electrode forming step shown in FIG. 1 is described next using the case where forming a polysilicon film or an amorphous silicon film by the CVD method, on an annealed hafnium oxynitride film by utilizing the single-wafer CVD apparatus configured as described above.

When the gate valve 157 opens, the negative pressure transfer device 13 carries the wafer 2 for film-forming in to the processing chamber 151 of the single-wafer CVD apparatus 150 serving as the fourth processing unit 34, from the wafer carry-in/out port 156 and transfers it onto the pushup pin on the wafer elevator unit 171.

The gate valve 157 closes the wafer carry-in/out port 156 when the negative pressure transfer device 13 exits the processing chamber 151.

Referring next to FIG. 6, when the gate valve 157 closes, an elevator drive device makes the rotating shaft 168 and the support shaft 164 rise to raise the rotation drum 169 and the heating unit 165 in the processing chamber 151. After being raised to a specified height, the wafer 2 is then in a state where transferred onto the susceptor 170.

The rotating shaft 168 next rotates the rotating drum 169.

The heater unit 165 heats the wafer 2 mounted on the susceptor 170 to reach a uniform target temperature across the entire surface.

The exhaust device exhausts the interior of the processing chamber 151 by way of the exhaust port 172 so that a specified processing pressure is reached within the interior of the processing chamber 151.

As shown in FIG. 6, the process gas 182 is supplied into the gas feed pipe 177 at the point in time where the temperature of the wafer 2 and pressure within the processing chamber 151 and the rotation of the rotating drum 169 have stabilized.

The process gas 182 supplied to the gas feed pipe 177 diffuses in the gas accumulator 176 and is uniformly sprayed from the multiple shower ports 175 in a shower towards the entire surface of the wafer 2. After making uniform contact across the entire surface of the wafer 2 on the susceptor 170, the process gas 182 sprayed from the shower ports 175 group as a shower, is suctioned into the exhaust port 172 by way of the exhaust buffer space 158 and evacuated.

The process gas 182 making contact with the wafer 2 forms a CVD film on the wafer 2.

The process conditions when forming a gate electrode from CVD film are described next using the forming of polysilicon (Poly-Si) film or amorphous silicon (a-Si) film as an example.

Monosilane (SiH₄) or disilane (Si₂H₆) is utilized for example as the process gas and the flow rate is 0.1 to 1 SLM.

In the case of phosphorus (P) doping, phosphine (PH₃) is mixed and the flow rate is 0.1 to 5 SLM.

The wafer temperature is regulated to a specified temperature within a range of 540 to 700° C.

The diluted nitrogen gas flow rate and the pressure controller device regulate the pressure within the processing chamber to a specified pressure within a range of 1,000 to 50,000 Pa.

Under these conditions, polysilicon film, (depending on conditions, amorphous silicon film) can usually be formed at a film forming rate of 50 to 100 nanometers per minute.

However, when using polysilicon film or amorphous silicon film as the high dielectric film (in this embodiment, hafnium oxynitride film) for the gate electrode, the polysilicon film or the amorphous silicon film must be formed at low temperatures below 500° C. in order to suppress effect on the high dielectric film so that this film forming that rate becomes 1 to 3 nanometer per minute.

Using the single-wafer CVD apparatus 150 to form the polysilicon film or amorphous silicon film with a final target film thickness of 100 to 150 nanometers, therefore requires a time of approximately 33 to 150 minutes.

In other words, using the single-wafer CVD apparatus 150 to form the polysilicon film or amorphous silicon film with the final target film thickness is not matched with each processing time for the other three steps; namely the high dielectric film forming step, the plasma nitriding step and the annealing step.

Whereupon, the initial gate electrode forming step in the present embodiment, is set to the same processing time or less as the step with the longest processing time among the other three steps, namely the high dielectric film forming step, plasma nitriding step, and annealing step; and the single-wafer CVD apparatus 150 forms the polysilicon film or amorphous silicon film.

For example, if the processing time for the high dielectric film forming step is four minutes, the processing time for the plasma nitriding step is three minutes, and the processing time for the annealing step is two minutes, then the processing time for the single-wafer CVD apparatus 150 of the cluster apparatus 10 to form the polysilicon film or amorphous silicon film is set to the same time as the step with the longest processing time among the other three steps, namely to the four minutes in the high dielectric film forming step.

In other words, the controller 37 in the cluster apparatus 10 presets the processing time on the single-wafer CVD apparatus 150 to four minutes, and controls to stop the supply of the process gas 182 when the four minutes elapse.

Therefore, when the processing time preset on the single-wafer CVD apparatus 150 of the cluster apparatus 10 elapses as described above, the supply of the process gas 182 is stopped.

Next, the process gas 182 remaining in the processing chamber 151 is removed by supplying inert gas from the inert gas supply device 180 and exhausting with the exhaust device.

The gate valve 157 then opens, the negative pressure transfer device 13 carries the wafer 2 now formed with a CVD film out from the processing chamber 151 in the reverse sequence of carry-in to the negative pressure transfer chamber 11, and the gate valve 157 then closes.

After implementing the high dielectric film forming step, plasma nitriding step, annealing step, and initial gate electrode forming step, the wafer may be cooled if required, using the first cooling unit 35 or the second cooling unit 36.

In the wafer unloading step shown in FIG. 1, after the initial gate electrode forming step in the cluster apparatus 10, the gate valve 18B opens the negative pressure transfer chamber 11 side in the carry-out chamber 15, the negative pressure transfer device 13 carries the wafer 2 from negative pressure transfer chamber 11 to the carry-out chamber 15, and transfers the wafer on the carry-out chamber temporary mounting stand of the carry-out chamber 15.

At this time, the gate valve 18A closes the positive pressure transfer chamber 16 side of the carry-out chamber 15 beforehand, and the exhaust device (not shown in drawing) exhausts the carry-out chamber 15 to a negative pressure. The gate valve 18B opens the negative pressure transfer chamber 11 side of the carry-out chamber 15 when the carry-out chamber 15 is depressurized to the preset pressure value, and wafer unloading is performed.

The gate valve 18B closes after wafer unloading step is completed.

The unloading operation of the wafer 2 processed in the initial gate electrode forming step, from the fourth processing unit 34 of the cluster apparatus 10 via the negative pressure transfer chamber 11 to the carry-out chamber 15 is performed in the fourth processing unit 34, the negative pressure transfer chamber 11 and the carry-out chamber 15 maintained at a vacuum. Therefore, a natural oxidation film is prevented from being formed on the surface of the film formed on the wafer 2 and foreign objects are prevented from adhering to the wafer 2 during the operation of unloading the wafer 2 from the fourth processing unit 34 to the carry-out chamber 15.

Incidentally, the operations for transferring the wafer 2 from the carry-in chamber 14 to the first processing unit 31, from the first processing unit 31 to the second processing unit 32, from the second processing unit 32 to the third processing unit 34, from the third processing unit 33 to the fourth processing unit 34, are all carried out under a vacuum state so that a natural oxidation film is prevented from being formed on the surface of the film formed on the wafer 2 and foreign objects are prevented from adhering to the wafer 2.

By repeating the above operation, each of the 25 wafers 2 carried in one batch into the carry-in chamber 14 is subjected in sequence to the high dielectric electrode film forming step by the first processing unit 31, the plasma nitriding step by the second processing unit 32, the annealing step by the third processing unit 33, and the initial gate electrode forming step by the fourth processing unit 34.

After the processing of the previously processed wafer 2 ends in the first processing unit 31 and the wafer 2 is carried into the second processing unit 32, the next wafer 2 is transferred to the first processing unit 31 and can be processed. In other words, when each processing unit in the processing sequence is empty, the next wafer 2 is carried in, and multiple wafers can be processed in parallel.

After the specified processing sequence for the 25 wafers 2 is completed, the now processed wafers 2 are accumulated in the temporary mounting stand of the carry-out chamber 15.

In the wafer unloading step shown in FIG. 1, nitrogen gas is supplied within the carry-out chamber 15 maintained at a negative pressure, and after the carry-out chamber 15 reaches atmospheric pressure, the gate valve 18A opens the positive pressure transfer chamber 16 side of the carry-out chamber 15. Next, the cap fitter/remover 26 of the pod opener 24 opens the cap on the empty pod 1 loaded on the mounting stand 25.

Next, the positive pressure transfer device 19 in the positive pressure transfer chamber 16 picks up the wafer 2 from the carry-out chamber 15, and carries it out to the positive pressure transfer chamber 16, and charges it in the pod 1 via the wafer carry-in/out port 23 of the positive pressure transfer chamber 16.

After the processed 25 wafers 2 are stored in the pod 1, the cap fitter/remover 26 of the pod opener 24 fits the cap of the pod 1 onto the wafer load/unload port, and the pod 1 is closed.

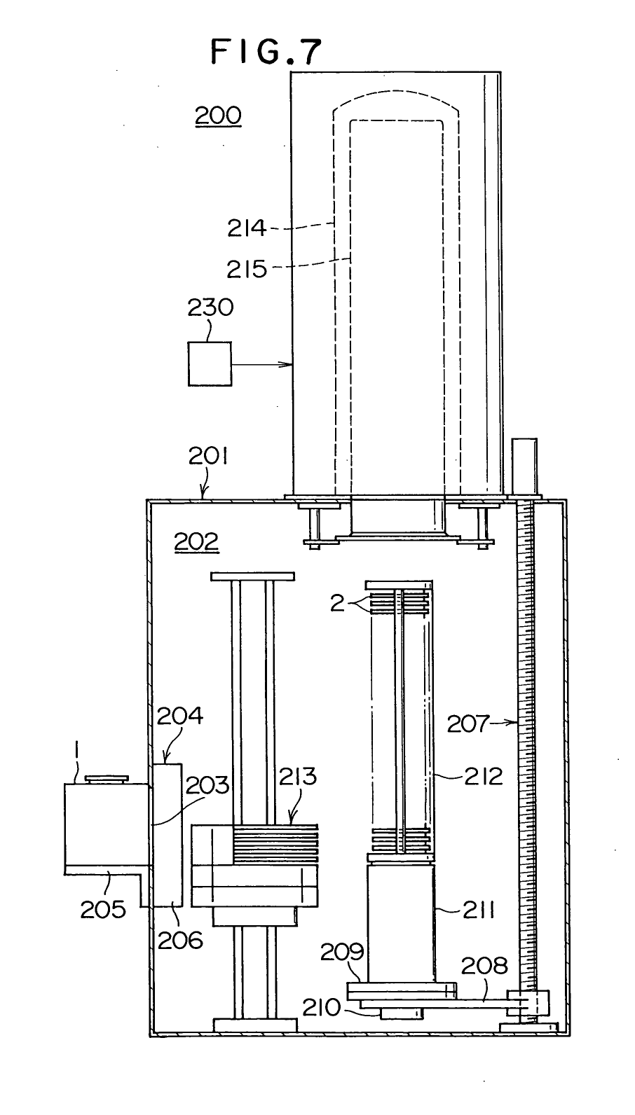

In this embodiment, when the four steps in the sequence performed in the cluster apparatus 10 are complete, the wafer 2 is transported by an internal process transport device to a batch type vertical hot wall CVD apparatus 200 (Hereafter, called batch CVD apparatus) shown in FIG. 7 while stored in an airtight state in the pod 1.

The remaining polysilicon film or amorphous silicon film is formed on the wafer 2 by the batch CVD apparatus 200 in order to form the gate electrode with the preset thickness.

The batch CVD apparatus 200 as shown in FIG. 7, includes a case 201 structured in rectangular parallelpiped box shape, and the case 201 constitutes a standby chamber 202.

A wafer carry-in/out port 203 is formed on the front wall of the case 201 for carrying the wafer 2 in and out of the case 201. A pod opener 204 is installed in the wafer carry-in/out port 203 to open and close the pod 1.

The pod opener 204 includes a mounting stand 205 for mounting the pod 1, and a cap fitter/remover 206 for fitting and removing the cap of the pod 1 mounted on the mounting stand 205. The wafer loading/unloading port of the pod 1 is opened or closed when the cap fitter/remover 206 fits or removes the cap of the pod 1 mounted on the mounting stand 205.

A process internal transport device not shown in the drawing, supplies and ejects the pod 1 to/from the mounting stand 205 of the pod opener 204.

A boat elevator 207 is installed in the standby chamber 202. A seal cap 209 is supported horizontally on the tip of an arm 208 of the boat elevator 207.

An electric motor 210 is installed below the seal cap 209. A rotating shaft of the electric motor 210 is inserted perpendicularly above the seal cap 209.

A heat insulating cap 211 is installed perpendicularly at the top end of the rotating shaft of the electric motor 210. A boat 212 is installed perpendicularly above the heat insulating cap 211. The electric motor 210 is structured so as to rotate the heat insulating cap 211 and the boat 212.

The boat 212 is structured to hold multiple wafers 2 arrayed perpendicularly.

A wafer transfer device 213 is installed in the standby chamber 202. The wafer transfer device 213 is structured to transport and transfer the wafer 2 between the boat 212 and the pod 1 of the pod opener 204.

The batch CVD apparatus 200 as shown in FIG. 7, contains a controller 230 for controlling to perform the remainder of the stopped processing (gate electrode forming step) in the cluster apparatus 10, in one processing chamber 216 as batch processing of multiple wafers.

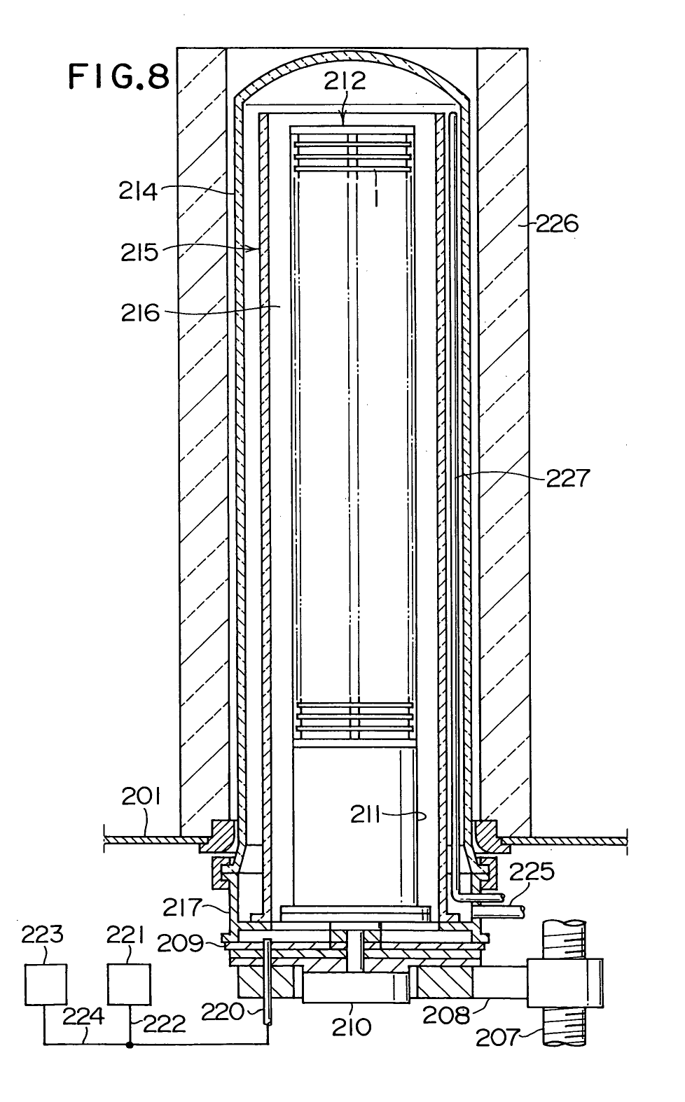

An outer tube 214 and an inner tube 215 are respectively installed with the center line positioned vertically above the rear edge of the case 201 as shown in FIG. 8. A heat-resistant material such as silicon carbide (SiC) or quartz (SiO₂) is utilized in the outer tube 214 on the external side. The outer tube 214 is formed in a cylindrical shape open in the bottom end and closed in the top end. The inner tube 215 installed on the inner side is formed in a cylindrical shape with an opening in the bottom end and open at the top end and utilizes a heat-resistant material such as silicon carbide or quartz. The cylindrical hollow interior of the inner tube 215 forms a processing chamber 216.

A manifold 217 of stainless steel for example, engages the bottom end of the outer tube 214 and the inner tube 217. The outer tube 214 and the inner tube 215 are held by this manifold 217. The manifold 217 is clamped to the case 201.

A gas feed pipe 220 connects to the seal cap 209. A process gas supply line 221 connected to a process gas supply device 222, and an inert gas supply line 224 connected to an inert gas supply device 223, are connected to the gas feed pipe 220.

One end of an exhaust pipe 225 connects to the manifold 217. The other end of the exhaust pipe 225 connects to an exhaust device (not shown in drawing) made up of a pump, etc.

A heater unit 226 is installed concentrically with the outer tube 214 on the outer side of the outer tube 214. The heater unit 226 is supported perpendicularly in the case 201. The heater unit 226 is structured to heat the entire processing chamber 216 to a uniform or a specified temperature distribution.

A thermocouple 227 for measuring the temperature of the processing chamber 216 is installed perpendicularly between the inner tube 215 and the outer tube 214. The heater unit 226 is structured to be performed the feedback control based on measurement results from the thermocouple 227.

The case where forming the polysilicon film or amorphous silicon film just of the remaining thickness in the remaining gate electrode forming step shown in FIG. 1 by batch processing of multiple wafers such as 100 wafers using the batch CVD apparatus 200 structured as related above is described next.

The wafers 2 whose processing was completed in the four steps in the cluster apparatus 10 are transferred to the batch CVD apparatus 200 for the remaining gate electrode forming step while stored as 25 wafers in the pod 1.

However, in the case where the ongoing forming of the polysilicon film or amorphous silicon film in the cluster apparatus 10 is stopped in the middle of the final target film thickness, and the wafer 2 is then taken outside the cluster apparatus 10, and then just the remaining thickness of polysilicon film or amorphous silicon film is formed in the batch CVD apparatus serving as the different apparatus from the cluster apparatus; a natural oxidization film might be formed on the surface of the polysilicon film or amorphous silicon film with the middle film thickness while the wafer 2 is being transported from the cluster apparatus 10 to the batch CVD apparatus 200.

However in the present embodiment, the wafer 2 formed with a polysilicon film or amorphous silicon film in the cluster apparatus 10, is stored in the pod 1 not exposed to the atmosphere so that the forming of a natural oxidization film on the surface of the polysilicon film or amorphous silicon film of the wafer 2 can be prevented.

The forming of a natural oxidation film can be prevented to an even further degree by replacing the gas within the pod 1, supplying an inert gas such as nitrogen gas into the pod 1 when the wafer is stored in the pod 1.

Moreover, even if a natural oxidization film is formed on the surface of the polysilicon film or amorphous silicon film on the wafer 2, performing monosilane (SiH₄) purge or dichlorosilane (SiH₂Cl₂) purge or hydrogen annealing prior to the remaining gate electrode forming step by the batch CVD apparatus 200 can remove the natural oxidation film.

The pod 1 storing multiple wafers 2 that are to be subjected to the remaining gate electrode forming step is then transferred onto the mounting stand 205 of the batch CVD apparatus 200.

In the wafer loading step shown in FIG. 1, when the cap fitter/remover 206 of the pod opener 204 opens the pod 1 placed on the mounting stand 205, the wafer transfer device 213 scoops up five wafers 2 at a time, and transfers them to the boat 212 held in standby in the standby chamber 202. The wafer transfer device 213 repeats this operation to transfer all the wafers 2 in the pod 1 into the boat 212.

After all the wafers 2 in the pod 1 were transferred to the boat 212, the pod opener 204 closes the cap on the pod 1. The now empty pod 1 is exchanged with another pod 1 storing multiple wafers 2 for performing the remaining gate electrode forming step and the same operation is repeated.

This operation is repeated until the preset 100 wafers 2 are charged into the boat 212.

The heater unit 226 raises the temperature within the processing chamber 216 and regulates it to a specified temperature.

The inert gas supply device 223 supplies inert gas by way of the inert gas supply line 224 and the gas feed pipe 220 to fill the interior of the processing chamber 216.

The boat elevator 207 raises the boat 212 when the boat 212 is filled with the specified number of wafer 2 and the boat 212 is carried into the processing chamber 216 in the interior of the inner tube 215 as shown in FIG. 8. When the boat 212 reaches the upper limit, the seal cap 209 seals the processing chamber 216 airtight.

The heater unit 226 maintains a specified temperature in the processing chamber 216 when the processing chamber 216 is sealed airtight.

Compared to the processing temperature in the initial gate electrode forming step in the cluster apparatus 10, the processing temperature in the remaining gate electrode forming step in this batch CVD apparatus 200 is set at a high temperature which is in a specified temperature range from 600 to 700° C.

The polysilicon film or amorphous silicon film is already formed on the surface of the high dielectric film (hafnium oxide film in this embodiment), so that the surface of the high dielectric film is not exposed at a comparatively high temperature to reducing gas such as monosilane gas or dichlorosilane gas, and therefore there is little effect on the high dielectric film.

Next, after the exhaust pipe 225 exhausts the processing chamber 216 to the specified vacuum state, the electric motor 210 rotates the heat insulating cap 211 and the boat 212.

In this state, the process gas supply device 221 supplies a process gas such as monosilane gas to the gas feed pipe 220 at a flow rate of 0.5 to 2 SLM.

If the polysilicon film or amorphous silicon film is to be doped with phosphorus, then phosphine is supplied at a flow rate of 0.01 to 0.1 SLM.

The monosilane gas supplied to the gas feed pipe 220 flows through the interior of the processing chamber 216 inside the inner tube 215 and reaches the top end of the inner tube 215, and then flows from the top opening on the inner tube 215 out between the outer tube 214 and the inner tube 215. The exhaust force from the exhaust pipe 225 drains away this monosilane gas.

While the monosilane gas rises in the processing chamber 216, a polysilicon film or amorphous silicon film is formed on the surface of the wafers 2 by the gas making contact with the wafers 2.

The rotation of the boat 212 at this time allows the gas containing silicon element to make uniform contact with the surface of the wafer 2 so that the polysilicon film or amorphous silicon film is formed at a uniform film thickness distribution on the wafer 2.

The film forming rate for the polysilicon film or amorphous silicon film using the batch CVD apparatus 200 here is several nanometers per minute when the processing temperature is 600 to 700° C.

Therefore, a polysilicon film or amorphous silicon film with a thickness of 4 to 12 nanometers formed in the cluster apparatus in a four minute period in the initial gate electrode forming step will require approximately 30 minutes to form the remaining film thickness of about 140 nanometers.

When the processing time (for example, 30 minutes) set in this way has elapsed, the boat elevator 207 lowers the boat 212 so that the boat 212 holding the processed wafers 2 is carried out from the processing chamber 216 into the standby chamber 202.

In the wafer unloading step shown in FIG. 1, the processed wafers 2 carried out into the standby chamber 202, are transferred to and stored in an empty pod 1 that was opened by the pod opener 204 from the boat 212. The pod opener 204 closes the pod 1 when the 25 processed wafers 2 are stored.

There are more wafers 2 (100 wafers) held at this time in the boat 212 than can be stored in the pod 1 (25 wafers) so that the multiple (4 units) empty pods 1 are supplied in sequence to the pod opener 204.

The polysilicon film or amorphous silicon film can be formed within one hour including the wafer transfer time, boat loading time and boat unloading time.

The embodiment as described above is capable of rendering the following effects.

Compared to the total processing time for implementing all steps including the high dielectric film forming step, plasma nitriding step, annealing step, and gate electrode forming step (forming of the final target film thickness) in the cluster apparatus 10; the throughput for the overall gate stack forming process can be improved by temporarily stopping the gate electrode forming step as the last processing in the cluster apparatus 10 to make the initial electrode forming step match the step with the longest processing time among the other three steps, and effectively shortening the standby time of the processing sequence in the cluster apparatus 10.

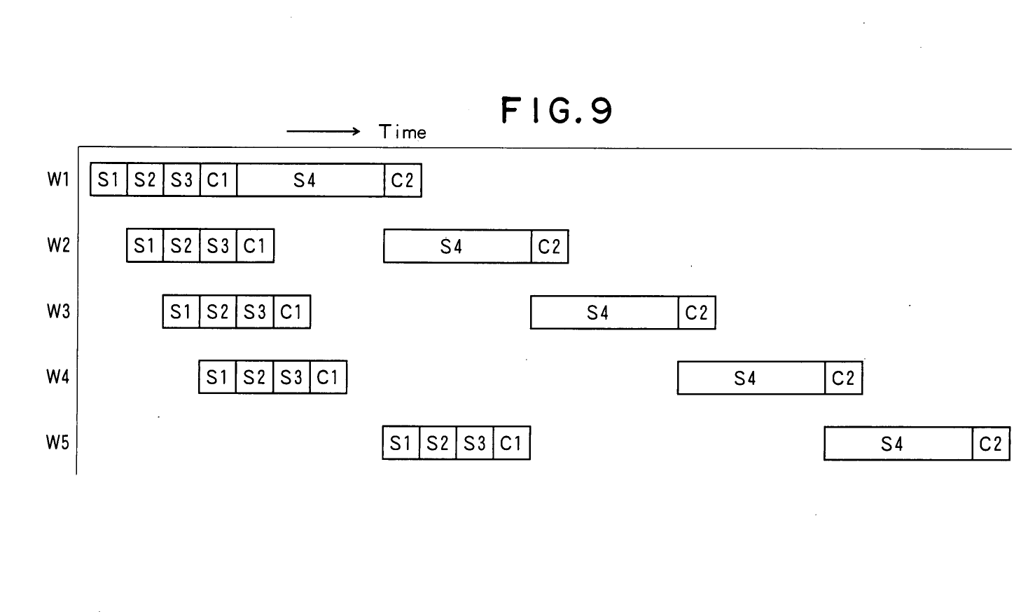

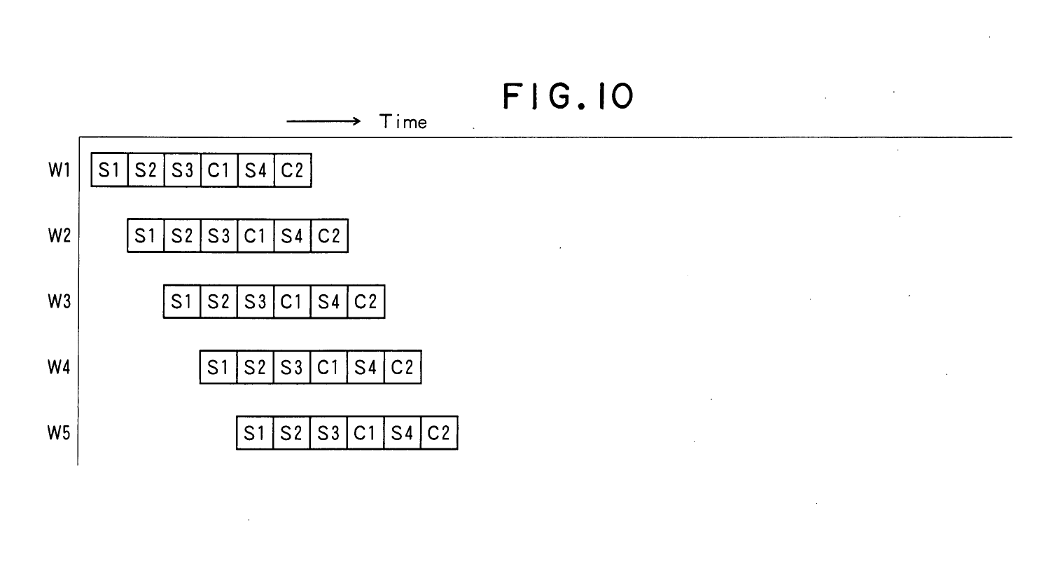

This measure is explained next while referring to FIG. 9 and FIG. 10.

In FIG. 9 and FIG. 10, the high dielectric film forming step is S1, the plasma nitriding step is S2, the annealing step is S3, and the gate electrode forming step is S4. Steps S1, S2, and S3 each require four minutes. When step S4 takes 20 minutes, the first wafer W1 is sequentially processed by way of steps S1 to S4 as shown in FIG. 9.

Here, after the respective processing in the annealing step S3 and the gate electrode forming step S4, the cooling steps C1, C2 are respectively performed using two cooling units capable of storing two wafers each (in other words, the two cooling units can store a total of four wafers).

Of course, when the high dielectric film forming step S1 for the first wafer W1 is completed, then an empty space is now available in the first processing unit 31 (ALD apparatus 40) for implementing that step S1, so that processing of a second wafer W2 in the high dielectric film forming step S1 can begin.

Likewise, when the plasma nitriding step S2 and the annealing step S3 for the first wafer W1 are completed, then the processing of the second wafer W2 in the plasma nitriding step S2 and the annealing step S3 can each begin.

The same is also true for the third wafer W3 and onward.

However, the processing time for the gate electrode forming step S4 is long compared to each of the other three steps S1, S2 and S3, so that the second wafer W2 through fourth wafer W4 (in other words, three wafers) that completed the three steps S1, S2 and S3, are respectively stored in the cooling unit, and wait for the first wafer W1 to complete the gate electrode forming step S4.

In this state, the three storage areas among the four wafer storage areas in the cooling unit are occupied by the three wafers W2, W3, and W4 so that only one area is empty.

The fifth wafer W5 should be able to begin processing in the high dielectric film forming step S1 when the fourth wafer W4 completes the high dielectric film forming step S1.

However, after the first wafer W1 has completed the gate electrode forming step S4, the first wafer W1 must be cooled in the cooling unit, and therefore the remaining one wafer storage area in the cooling unit needs empty. The fifth wafer W5 must therefore wait for a cooling unit to become available, so that even if the fourth wafer W4 completes the high dielectric film forming step S1, it cannot immediately begin the high dielectric film forming step S1.

Even assuming that after completing the high dielectric film forming step S1, the fourth wafer W4 undergoes the plasma nitriding step S2 in parallel with the fifth wafer W5 starting the high dielectric film forming step S1; the annealing step S3 for the fifth wafer W5 will end prior to the gate electrode forming step S4 for the first wafer W1, and the one remaining wafer storage area in the cooling units will be occupied by the fifth wafer W5. The first wafer W1 cannot therefore be placed in the cooling unit after it completes the gate electrode forming step S4 and so the operation is deadlocked.

As can be seen in the above description, when the step with the longest processing time (job time) is the final step (S4 in FIG. 9), in a consecutive processing sequence with multiple steps S1 through S4, then a waiting time occurs that causes a drop in the throughput of the overall process.

In contrast to the above, if the processing step sequence S1 to S4 with equal processing times is implemented, then if the processing times for the four steps S1, S2, S3, S4 and further the cooling time for the cooling steps C1, C2 are for example each set to four minutes, then as shown in FIG. 10, there is no standby time, and each of the steps S1, S2, S3, S4, C1, and C2 proceeds smoothly so that the throughput is large compared to that in FIG. 9.

For example in the gate electrode forming step S4 in FIG. 9, if the forming of the gate electrode with the target film thickness of 100 nanometers requires 20 minutes, then the total time required for the gate electrode forming step S4 until processing of 100 wafers is completed is 100 wafers×20 minutes=2,000 minutes=about 33 hours. The throughput for one hour is therefore 3 wafers.

In contrast to the above, on a gate electrode formed at a thickness of only 20 nanometers in the cluster apparatus 10 but having a gate electrode target film thickness of 100 nanometers, if the remaining 80 nanometers could be film-formed on 100 wafers 2 by batch processing in the batch CVD apparatus 200, then each of the processing times in the high dielectric film forming step S1, the plasma nitriding step S2, the annealing step S3 and the initial gate electrode forming step S4 can be unified to a time of 4 minutes. Moreover, the total time for the gate electrode forming step S4 required through completion of processing in a cluster apparatus handling 100 wafers can be shortened to 100 wafers×4 minutes=about 7 hours.

If the processing time in the remaining gate electrode forming step for the 100 wafers in the batch CVD apparatus 200 is set to approximately one hour, then the throughput is limited by the longest time so that the throughput is 100/7=about 14 wafers per hour.

However, when using different types of processing apparatus such as the batch CVD apparatus 200 and the cluster apparatus 10, or when changing the processing conditions to form the gate electrode in two stages; then the first layer of the gate electrode formed in the cluster apparatus 10 is an amorphous state, and the second layer of the gate electrode formed in the batch CVD apparatus 200 is a polycrystalline state.

However, in this embodiment, when forming the second layer of the gate electrode in the batch CVD apparatus 200, the first layer of the gate electrode is polycrystalline, and at the point that the second layer of the gate electrode is completed, the two layers in crystalline state and film quality are roughly equivalent. In other words, the first layer and the second layer can be made homogenous when forming the second layer of the gate electrode in the batch CVD apparatus 200.

The gate electrode can be completely crystallized, and the two layers can be made identical to form one consecutive layer by performing ion implantation or active annealing (annealing performed at temperatures of 1,000° C. or higher) after the gate stack process.

The present invention is not limited to these embodiments and needless to say all manner of changes and adaptations are allowable that do not depart from the scope or spirit of the invention.

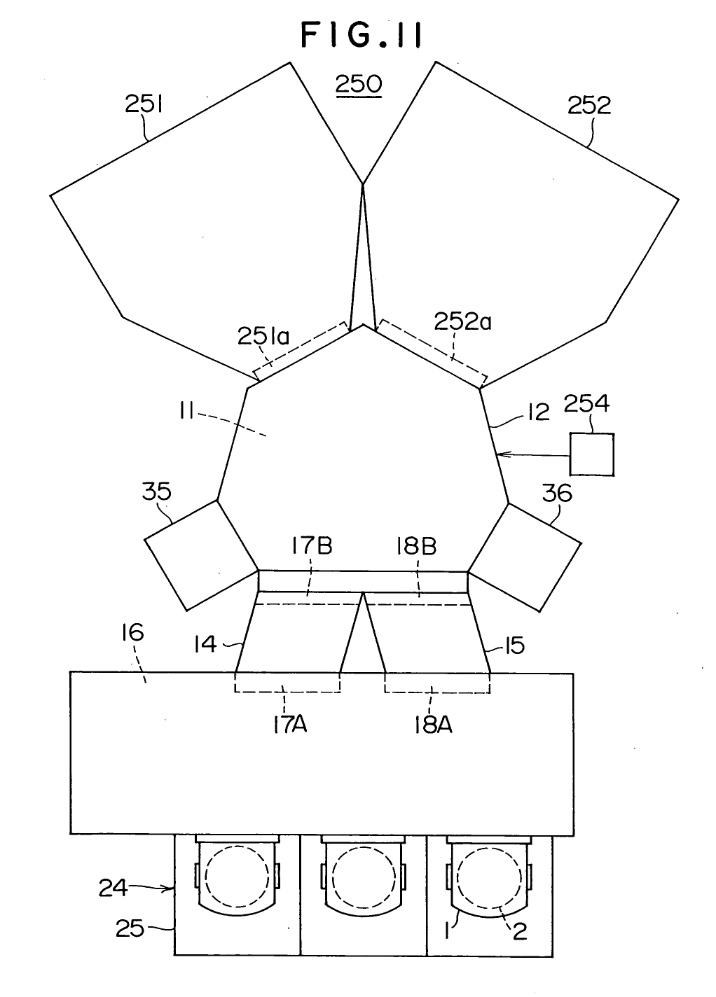

For example, performing the remaining gate electrode forming step at one time on multiple wafers is not limited to use of the batch CVD apparatus 200. As shown in FIG. 11, a single-wafer multi-chamber apparatus (Hereafter called, multi-chamber apparatus) 250 that includes multiple single-wafer CVD apparatus equivalent to the single-wafer CVD apparatus 150 in the previous embodiment may be utilized.

In FIG. 11, two single-wafer CVD apparatus 251, 252 serving as multiple processing chambers for batch processing of multiple substrates in the same process (remaining gate electrode forming step) for the substrates; are respectively connected to two side walls of the negative pressure transfer chamber case 12 by way of gate valves 251a, 252a so as to connect the negative pressure transfer chamber 11.

This multi-chamber apparatus 250 includes a controller 254 for control to implement batch processing on multiple wafers in the two single-wafer CVD apparatus 251, 252 serving as multiple processing chambers for performing the remainder of the processing that was stopped in the cluster apparatus 10 serving as the consecutive processing device.

The cluster apparatus 10 in this embodiment is also capable for example of unifying each of the processing times in the high dielectric film forming step, the plasma nitriding step, the annealing step, and the initial gate electrode forming step to four minutes, and therefore improves the throughput of the overall gate stack forming process.

When forming just the remainder of the polysilicon film or amorphous silicon film thickness using the two single-wafer CVD apparatus 251, 252 in the multi-chamber apparatus 250 shown in FIG. 11, a polysilicon film or amorphous silicon film is already formed in the initial gate electrode forming step on the surface of the high dielectric film formed on the wafer 2, so that the high dielectric film (in this embodiment, hafnium oxynitride film) is not directly exposed at comparatively high temperatures to a reducing gas such as monosilane gas or disilane gas, and these gases have little effect on that high dielectric film.

The processing temperature in the single-wafer CVD apparatus 251, 252 can therefore be set to a comparatively high temperature, and the film-forming rate can be increased.

The processing conditions when forming polysilicon film or amorphous silicon film using the single-wafer CVD apparatus 251, 252 are described here as follows.

The process gas is for example, monosilane gas or disilane gas at a flow rate of 0.1 to 1 SLM.

In the case of phosphorus (P) doping, the phosphine is mixed and the flow rate is 0.1 to 5 SLM.

The wafer temperature is regulated to a specified temperature within a range of 540 to 700° C.

The diluted nitrogen gas flow rate and the pressure controller device regulate the pressure within the processing chamber to a specified pressure within a range of 1,000 to 50,000 Pa.

Under these conditions, film can be formed at a film forming rate of 50 to 100 nanometers per minute. In the polysilicon film or amorphous silicon film where 4 to 12 nanometers was formed in a four minute period by the cluster apparatus in the initial gate electrode forming step, the forming of the remaining film with a thickness of approximately 140 nanometers can be performed in 2 to 3 minutes.

Each of the single-wafer CVD apparatus can form film on a single wafer in 2 to 3 minutes so that film-forming of 100 wafers can be completed in 100 to 150 minutes if tow single-wafer CVD apparatus 251, 252 are used. If the processing time for each step is four minutes, the total processing time for 100 wafers in the cluster apparatus is 100 wafers×4 minutes=400 minutes=about 7 hours. The throughput, however, is limited by the longer processing time so that the throughput is 100/7=about 14 wafers per hour.

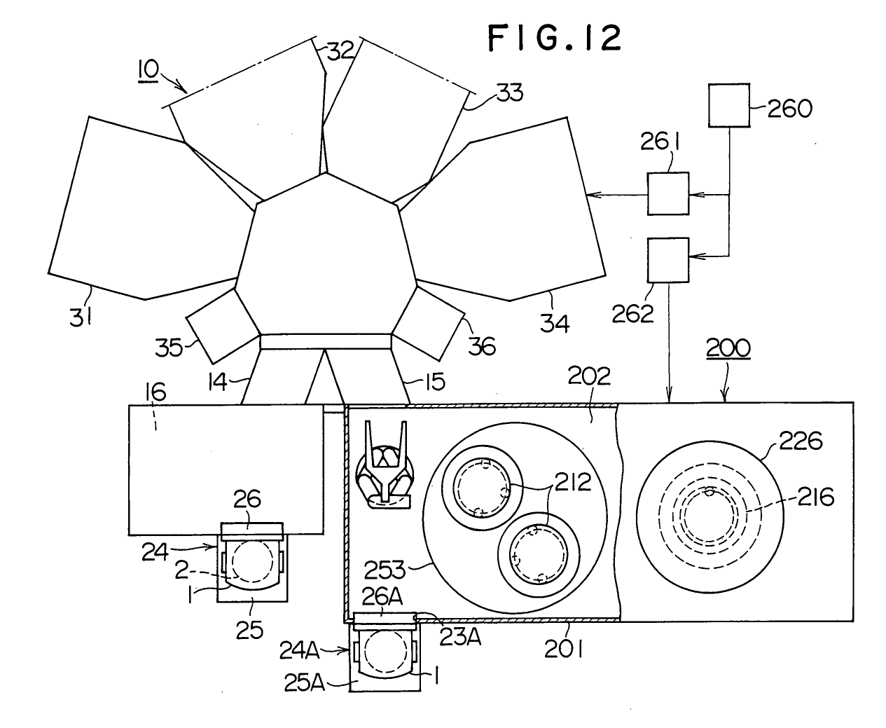

The batch CVD apparatus 200 may be connected to the cluster apparatus 10 as shown in FIG. 12.

In this case, the standby chamber 202 of the batch CVD apparatus 200 is preferably connected to the carry-out chamber 15 of the cluster apparatus 10.

Preferably, a wafer carry-out port 23A, a mounting stand 25A for loading the pod 1 and a pod opener 24A including a cap fitter/remover 26A for fitting and removing the cap on the pod 1 loaded on the mounting stand 25A are installed in the standby chamber 202 of the case 201, as a structure capable of carrying the wafers 2 that completed the remaining gate electrode forming step in the batch CVD apparatus 200, from the standby chamber 202 to an external section.

Moreover, a first subcontroller 261 for controlling to stop in the middle, the ongoing final process (gate electrode forming step) in the consecutive processing in the cluster apparatus 10, a second subcontroller 262 for controlling to execute the remaining process (remaining gate electrode forming step) that was stopped in the cluster apparatus 10 as batch processing of multiple wafers in one processing chamber 216 and, a main controller 260 for overall control of the first subcontroller 261 and the second subcontroller 262, are preferably installed.

In this embodiment, the wafer 2 that completed the initial gate electrode forming step in the cluster apparatus 10, is transferred into the standby chamber 202 by way of the carry-out chamber 15 and transferred to the boat 212.

Then at the point that the boat 212 is filled with the specified number of wafers, for example 25 wafers, the boat 212 is carried into the processing chamber 216 of the batch CVD apparatus 200, and the remaining thickness of the polysilicon film or amorphous silicon film is formed.

Performing the remaining gate electrode forming step on 25 wafers at a time or in other words, performing this step in a unit of the wafers stored in one pod in the batch CVD apparatus 200, has the advantage of shortening the standby time in the batch CVD apparatus 200, and drastically shortening the tact time (time from wafer carry-in until wafer carry-out) compared to the case where performing the remaining gate electrode forming step in a unit of 100 wafers.

After forming the film, the boat 212 is carried out from the processing chamber 216, and the now processed wafers 2 are sequentially transferred form the boat 212, and stored in an empty pod 1 that was placed on the mounting stand 25A and opened by the pod opener 24A.

In this case, multiple boats 212 may be prepared as shown in FIG. 12, and the boats 212 replaced by a boat changer 253.

Multiple boats 212 and processing chambers 216 may also be installed.

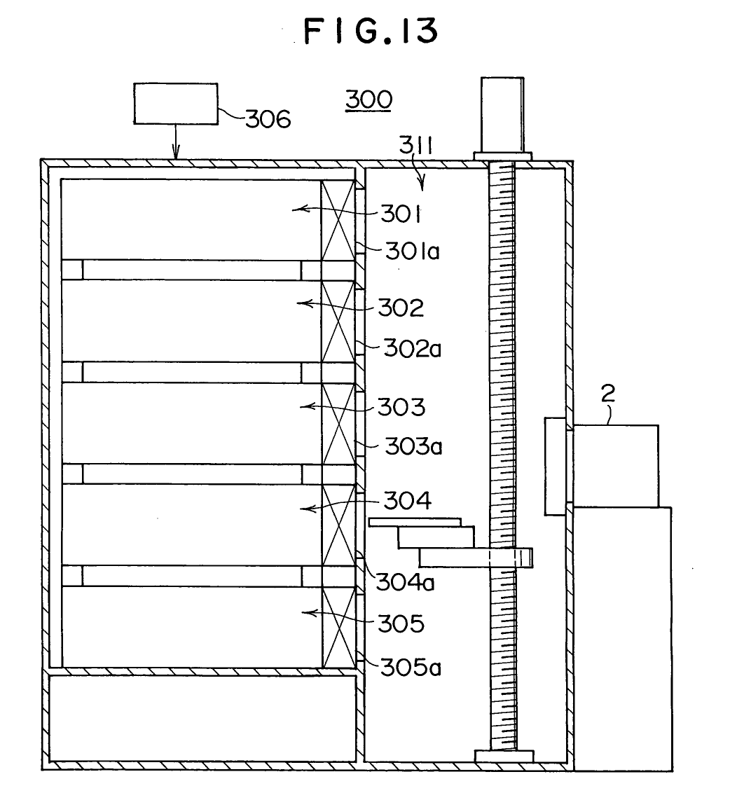

A single-wafer multi-chamber apparatus (multi-chamber apparatus) may be structured as shown in FIG. 13.

The multi-chamber apparatus 300 shown in FIG. 13, contains five single-wafer CVD apparatus 301, 302, 303, 304, and 305 stacked vertically as multiple processing chambers for batch processing of multiple substrates in the same process (remaining gate electrode forming step) and installed adjoining a negative pressure transfer chamber 311. Gate valves 301a, 302a, 303a, 304a, and 305a each are installed between the single-wafer CVD apparatus 301, 302, 303, 304, and 305 and the negative pressure transfer chamber 311.

The multi-chamber apparatus 300 contains a controller 306 for performing batch processing of multiple substrates in the five single-wafer CVD apparatus serving as processing chambers for the remaining process that was stopped in the consecutive processing by the cluster apparatus 10.

In the present embodiment, five single-wafer CVD apparatus can batch process five wafers in the remaining gate electrode forming step so that if each of the single-wafer CVD apparatus forms film in 2 to 3 minutes per wafer, then film can be formed on 100 wafers in 40 to 60 minutes. In other words, the processing time for the remaining gate electrode forming step in this embodiment can be shortened compared to the case where using the multi-chamber apparatus 250 shown in FIG. 11.

Moreover, the five single-wafer CVD apparatus are stacked vertically so that the floor surface area occupied by the multi-chamber apparatus 300 can be reduced.

In the above embodiment, the case where forming the gate electrode from polysilicon film or an amorphous silicon film was described. However, the present invention also applies to the forming of metal gate electrodes (Hereafter, called metal electrodes) as the gate electrodes.

In that case, the metal electrode may be formed by the ALD method utilizing a single-wafer ALD apparatus as shown in FIG. 3, or by the CVD method using the single-wafer CVD apparatus shown in FIG. 6.

The metal electrode film-forming rate of a few A per minute in the single-wafer ALD apparatus is especially slow so that by stopping the ongoing metal electrode forming step in the single-wafer ALD apparatus to match the film-forming time in steps other than the metal electrode forming step, and then forming the remainder of the film for the metal electrode using the batch ALD apparatus or batch CVD apparatus, the throughput of the entire gate stack forming process using metal electrodes can be improved.

Exposing a metal film with a thickness of approximately 20 Å to the atmosphere might cause oxidation not only on the film surface but across the entire film depending on the metal electrode film type. In such cases, the time that film forming is stopped in the single-wafer ALD apparatus should preferably be extended so that even if oxidation occurs in the vicinity of the film surface, film that is not oxidized will still remain (so that oxidation occurs only in the vicinity of the film surface and the overall film is not oxidized).

Materials for forming the metal electrode is TiN, TaN, NiSi, PtSi, TaC, TiSi, Ru, or SiGe.

In the above embodiment, the MOSFET gate stack forming process was described. However, the same effect of the invention can be obtained when applied to the capacitor forming process for memories such as DRAM that includes the barrier metal forming step, the capacitor insulating film forming step, and the upper metal electrode forming step, on the wafer forming the lower metal electrode.

In other words, in the case where performing the barrier metal forming step using the ALD apparatus to form a film of barrier metal on the wafer where a lower metal electrode was already formed; and then performing the capacitor insulating film forming step using the ALD apparatus to form a capacitive insulating film, and further performing the upper metal electrode forming step using the ALD apparatus to form an upper metal electrode; the upper metal electrode forming step requires an extremely long amount of time compared to the barrier metal forming step and the capacitor insulating film forming step.

The present invention, however, improves the throughput since the cluster apparatus consecutively performs the barrier metal forming step, the capacitor insulating film forming step and the upper metal electrode forming step on one substrate at a time; stops in the middle, the ongoing final upper metal electrode forming step and, performs the remainder of the stopped process by batch processing of multiple substrates in other processing chambers.

The material for forming the capacitor upper electrode is Al, TiN, Ru, RuO₂, SRO (SrₓRu_{y}O₃), Ir, or Pt.

The electrode forming gas used in the electrode forming step may be selected as needed according to the desired electrode forming material.

The material for forming the high dielectric film is not limited to hafnium oxynitride.

The material for the high dielectric film for forming the gate insulating film is HfSiOₓ, Ta₂, O₅, Al₂O₃, ZrO₂, HfAlOₓ, HfAlON, La₂O₃, Y₂O₃, or LaₓAl_{y}O_{z}.

Materials for forming the capacitor insulating film is BST((Ba,Sr)TiO₃), or STO(SrTiO₃).

The substrate for processing is not limited to wafers, and may include substrates such as liquid crystal panels and glass substrates in processes for manufacturing LCD devices.

1. A manufacturing method for semiconductor devices comprising the steps of:
performing different processes consecutively on at least one substrate at a time,
stopping in the middle, the final ongoing process among the consecutive processes, and
performing the remainder of the final process that was stopped as batch processing of the multiple substrates.

2. The manufacturing method for semiconductor devices according to claim 1, wherein the batch processing of the multiple substrates is performed in a processing chamber storing the multiple substrates.

3. The manufacturing method for semiconductor devices according to claim 1, wherein the batch processing of the multiple substrates is performed using multiple processing chambers storing at least one substrate in each processing chamber.

4. The manufacturing method for semiconductor devices according to claim 1, wherein the batch processing of the multiple substrates is performed in a unit of the substrates stored in one substrate storage container.

5. The manufacturing method for semiconductor devices according to claim 1, wherein the batch processing of the multiple substrates is performed in a unit of 25 substrates.

6. The manufacturing method for semiconductor devices according to claim 1, wherein the batch processing of the multiple substrates is performed using different apparatus from the apparatus for performing the consecutive processes.

7. The manufacturing method for semiconductor devices according to claim 1, wherein each process in the consecutive processes is performed in different processing chambers respectively.

8. The manufacturing method for semiconductor devices according to claim 1, wherein the processing time for the final process in the consecutive processes is set to the same or shorter processing time than the processing time for the process with the longest processing time among the other processes in the consecutive processes.

9. The manufacturing method for semiconductor devices according to claim 1, wherein the consecutive processes include at least a step of forming an insulating film on the substrate, and a step of forming an electrode on the insulating film, and the final process is the step of forming the electrode.

10. The manufacturing method for semiconductor devices according to claim 1, wherein the consecutive processes include at least a step of forming a High-k film on the substrate, and a step of forming an electrode on the High-k film, and the final process is the step of forming the electrode.

11. The manufacturing method for semiconductor devices according to claim 1, wherein the consecutive processes include at least a step of forming a High-k film on the substrate, a step of nitriding the High-k film, a step of annealing the nitrided High-k film, and a step of forming an electrode on the High-k film after annealing, and the final process is the step of forming the electrode.

12. A substrate processing apparatus comprising:
a consecutive processing apparatus including multiple processing chambers for performing different processes consecutively on at least one substrate at a time, and a controller for controlling to stop in the middle, the final ongoing process in the consecutive processes and;
a batch processing apparatus including one or multiple processing chambers for batch processing multiple substrates with identical process, and a controller for controlling to perform the remainder of the process that was stopped in the consecutive processing apparatus, in the one or multiple processing chambers as batch processing of the multiple substrates.
